(19) United States
(12) Patent Application Publication
(10) Pub. No.: US 2024/0364294 A1
(43) Pub. Date: Oct. 31, 2024

(54) ACOUSTIC WAVE DEVICE AND FILTER DEVICE

(71) Applicant: Murata Manufacturing Co., Ltd., Nagaokakyo-shi (JP)

(72) Inventor: Katsuya DAIMON, Nagaokakyo-shi (JP)

(21) Appl. No.: 18/771,377

(22) Filed: Jul. 12, 2024

Related U.S. Application Data
(63) Continuation of application No. PCT/JP2023/001709, filed on Jan. 20, 2023.
(60) Provisional application No. 63/401,248, filed on Aug. 26, 2022.
(60) Provisional application No. 63/301,580, filed on Jan. 21, 2022.

(51) Int. Cl. H03H 9/02; H03H 9/56

(52) U.S. Cl. CPC H03H 9/02015; H03H 9/02228; H03H 9/562

(57) ABSTRACT

An acoustic wave device includes a support including a support substrate, a piezoelectric layer on the support, and an IDT electrode on the piezoelectric layer and including busbars and electrode fingers. In plan view when viewed in a lamination direction of the support and the piezoelectric layer, an acoustic reflector overlaps at least a portion of the IDT electrode on the support. When a thickness of the piezoelectric layer is defined as d and a center-to-center distance between the electrode fingers adjacent to each other is defined as p, d/p is about 0.5 or smaller. Mass addition films are located over at least one of pair of edge regions and a gap region adjacent to the edge region and aligned in an electrode finger facing direction. The mass addition films are not located on at least a portion between the adjacent electrode fingers.

### CROSS REFERENCE TO RELATED APPLICATIONS

This application claims the benefit of priority to Provisional Application No. 63/401,248 filed on Aug. 26, 2022 and Provisional Application No. 63/301,580 filed on Jan. 21, 2022 and is a Continuation Application of PCT Application No. PCT/JP2023/001709 filed on Jan. 20, 2023. The entire contents of each application are hereby incorporated herein by reference.

### BACKGROUND OF THE INVENTION

### 1. Field of the Invention

The present invention relates to acoustic wave devices and filter devices.

### 2. Description of the Related Art

In the related art, an acoustic wave device has been widely used for a filter or the like of a mobile phone. In recent years, as disclosed in US Pat. No. 10,491,192, an acoustic wave device using a bulk wave in a thickness shear mode has been proposed. In the acoustic wave device, a piezoelectric layer is provided on a support. A pair of electrodes are provided on the piezoelectric layer. The pair of electrodes face each other on the piezoelectric layer, and are connected to mutually different potentials. An alternating current (AC) voltage is applied between the electrodes to excite the bulk wave in the thickness shear mode.

Japanese Unexamined Patent Application No. 2012-186808 discloses an example of an acoustic wave device using a piston mode. In the acoustic wave device, an IDT electrode (Interdigital Transducer) is provided on a piezoelectric substrate. The IDT electrode has a central region and a pair of edge regions. The pair of edge regions face each other with a central region interposed therebetween in an extending direction of a plurality of electrode fingers. In the pair of edge regions, a dielectric layer or the like is provided on the IDT electrode. In this manner, the piston mode is established by forming a plurality of regions having different acoustic velocities in the extending direction of the plurality of electrode fingers. In this manner, a transverse mode is reduced or prevented.

### SUMMARY OF THE INVENTION

The present inventor has discovered the following. Whereas deterioration in a loss can be reduced or prevented by providing a dielectric layer as a mass addition film in an edge region in the acoustic wave device using the bulk wave in the thickness shear mode, unnecessary waves are generated in the vicinity of a resonant frequency and in the vicinity of an anti-resonant frequency.

Example embodiments of the present invention provide acoustic wave devices and filter devices that reduce or prevent unnecessary waves in a vicinity of a resonant frequency or in a vicinity of an anti-resonant frequency even when a mass addition film is provided in an edge region.

According to an example embodiment of the present invention, an acoustic wave device includes a support including a support substrate, a piezoelectric layer provided on the support and including lithium tantalate or lithium niobate, and an IDT electrode provided on the piezoelectric layer and including a pair of busbars and a plurality of electrode fingers, in which, in plan view in a lamination direction of the support and the piezoelectric layer, an acoustic reflector overlaps with at least a portion of the IDT electrode in the support, when a thickness of the piezoelectric layer is defined as d and a center-to-center distance between the electrode fingers adjacent to each other is defined as p, d/p is about 0.5 or smaller, some electrode fingers of the plurality of electrode fingers are connected to one busbar of the pair of busbars, remaining electrode fingers of the plurality of electrode fingers are connected to an other busbar, and the some electrode fingers connected to the one busbar and the remaining electrode fingers connected to the other busbar are interdigitated with each other, an extending direction of the plurality of electrode fingers is defined as an electrode finger extending direction, and a direction perpendicular to the electrode finger extending direction is defined as an electrode finger facing direction, when viewed in the electrode finger facing direction, a region in which the adjacent electrode fingers overlap each other is an intersecting region, a region located between the intersecting region and the pair of busbars is a pair of gap regions, and the intersecting region includes a central region and a pair of edge regions positioned with the central region interposed therebetween in the electrode finger extending direction, the acoustic wave device further includes a plurality of mass addition films provided over at least one edge region of the pair of edge regions and the gap region adjacent to the at least one edge region, and aligned in the electrode finger facing direction, and the plurality of mass addition films are not located in at least a portion between the adjacent electrode fingers.

In a filter device according to another example embodiment of the present invention, a filter device includes at least one series arm resonator, at least one parallel arm resonator, at least one first acoustic wave resonator included in the at least one series arm resonator, and at least one second acoustic wave resonator included in the at least one parallel arm resonator, in which each of the first acoustic wave resonator and the second acoustic wave resonator is the acoustic wave device according to another example embodiment of the present invention, and a thickness of the plurality of mass addition films of the second acoustic wave resonator is smaller than a thickness of the plurality of mass addition films of the first acoustic wave resonator.

In a filter device according to yet another example embodiment of the present invention, a filter device includes at least one series arm resonator, at least one parallel arm resonator, at least one first acoustic wave resonator included in the at least one series arm resonator, and at least one second acoustic wave resonator included in the at least one parallel arm resonator, in which each of the first acoustic wave resonator and the second acoustic wave resonator is the acoustic wave device according to another example embodiment of the present invention, and an average value of areas of the plurality of mass addition films of the second acoustic wave resonator in plan view is greater than an average value of areas of the plurality of mass addition films of the first acoustic wave resonator in plan view.

In still another example embodiment of the present invention, a filter device includes a plurality of acoustic wave resonators including at least one series arm resonator and at least one parallel arm resonator. At least one acoustic wave resonator of the series arm resonator and the parallel arm resonator is the acoustic wave device according to another example embodiment of the present invention.

According to example embodiments of the present invention, it is possible to provide acoustic wave devices and filter devices that reduce or prevent unnecessary waves in a vicinity of a resonant frequency or in a vicinity of an anti-resonant frequency even when a mass addition film is provided in an edge region.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic plan view of an acoustic wave device according to a first example embodiment of the present invention.

FIG. 2 is a schematic cross-sectional view taken along line I-I in FIG. 1.

FIG. 3 is a schematic plan view of an acoustic wave device of a first comparative example.

FIG. 4 is a view showing admittance frequency characteristics in the first example embodiment, the first comparative example, and a second comparative example of the present invention.

FIG. 5 is a view showing excitation intensity of unnecessary waves in the first comparative example.

FIG. 6 is a schematic plan view for describing dimensions of a mass addition film.

FIG. 7 is a view showing a relationship between dimensions in an electrode finger extending direction of a portion located in a gap region in the mass addition film and the admittance frequency characteristics.

FIG. 8 is a view showing a relationship between the dimensions in the electrode finger extending direction of the portion located in the gap region in the mass addition film and a return loss.

FIG. 9 is a view showing the return loss when silicon oxide is used as a material of the mass addition film in the first example embodiment, when tantalum oxide is used as a material of the mass addition film in the first example embodiment of the present invention, and in the first comparative example.

FIG. 10 is a schematic elevational cross-sectional view of an acoustic wave device according to a modification example of the first example embodiment of the present invention.

FIG. 11 is a view showing the admittance frequency characteristics when silicon oxide is used as the material of the mass addition film in a second example embodiment of the present invention and the first comparative example.

FIG. 12 is a view showing the admittance frequency characteristics when tantalum oxide is used as the material of the mass addition film in the second example embodiment of the present invention and the first comparative example.

FIG. 13 is a view showing a relationship between the dimensions in the electrode finger extending direction of the gap region and the admittance frequency characteristics.

FIG. 14 is a schematic plan view of an acoustic wave device according to a third example embodiment of the present invention.

FIG. 15 is a schematic plan view of an acoustic wave device according to a fourth example embodiment of the present invention.

FIG. 16 is a view showing the admittance frequency characteristics in the second example embodiment and a modification example of the fourth example embodiment of the present invention.

FIG. 17 is a schematic plan view of an acoustic wave device according to a fifth example embodiment of the present invention.

FIG. 18 is a schematic plan view of an acoustic wave device according to a sixth example embodiment of the present invention.

FIG. 19 is a schematic plan view of an acoustic wave device of a first reference example.

FIG. 20 is a view showing the admittance frequency characteristics in the first example embodiment of the present invention, the sixth example embodiment of the present invention, and the first reference example.

FIG. 21 is a schematic plan view of an acoustic wave device according to a seventh example embodiment of the present invention.

FIG. 22 is a schematic plan view of an acoustic wave device according to an eighth example embodiment of the present invention.

FIG. 23 is a schematic plan view of an acoustic wave device according to a modification example of the eighth example embodiment of the present invention.

FIG. 24 is a circuit diagram of a filter device according to a ninth example embodiment of the present invention.

FIG. 25 is a circuit diagram of a filter device according to a tenth example embodiment of the present invention.

FIG. 26 is a schematic plan view of a fourth acoustic wave resonator according to the tenth example embodiment of the present invention.

FIG. 27 is a view showing the admittance frequency characteristics of a third acoustic wave resonator and the fourth acoustic wave resonator in the tenth example embodiment of the present invention.

FIG. 28 is a schematic plan view of a fifth acoustic wave resonator in an eleventh example embodiment of the present invention.

FIG. 29 is a view showing the admittance frequency characteristics of a fifth acoustic wave resonator in the eleventh example embodiment of the present invention and acoustic wave resonators in a second reference example and a third reference example.

FIG. 30 is a schematic plan view of a sixth acoustic wave resonator according to a twelfth example embodiment of the present invention.

FIG. 31 is a view showing the admittance frequency characteristics of a third acoustic wave resonator, a fifth acoustic wave resonator, and the sixth acoustic wave resonator in the twelfth example embodiment of the present invention.

FIG. 32A is a schematic perspective view showing an appearance of the acoustic wave device using a bulk wave in a thickness shear mode, and FIG. 32B is a plan view showing an electrode structure on a piezoelectric layer.

FIG. 33 is a cross-sectional view of a portion taken along line A-A in FIG. 32A.

FIG. 34A is a schematic elevational cross-sectional view showing a Lamb wave propagating through a piezoelectric film of the acoustic wave device, and FIG. 34B is a schematic elevational cross-sectional view showing the bulk wave in the thickness shear mode which propagates through the piezoelectric film of the acoustic wave device.

FIG. 35 is a view showing an amplitude direction of the bulk wave in the thickness shear mode.

FIG. 36 is a view showing resonance characteristics of the acoustic wave device using the bulk wave in the thickness shear mode.

FIG. 37 is a view showing a relationship between d/p and a fractional bandwidth as a resonator when a center-to-center distance of adjacent electrodes is defined as p and a thickness of a piezoelectric layer is defined as d.

FIG. 38 is a plan view of the acoustic wave device using the bulk wave in the thickness shear mode.

FIG. 39 is a view showing resonance characteristics of an acoustic wave device of a reference example in which spurious appears.

FIG. 40 is a view showing a relationship between the fractional bandwidth and a phase rotation amount of impedance of the spurious standardized at 180 degrees as the magnitude of the spurious.

FIG. 41 is a view showing a relationship between d/2p and a metallization ratio MR.

FIG. 42 is a view showing a map of the fractional bandwidth with respect to Euler angles (0°, θ, ψ) of LiNbO₃ when d/p is infinitely close to 0.

FIG. 43 is an elevational cross-sectional view of the acoustic wave device having an acoustic multilayer film.

### DETAILED DESCRIPTION OF THE EXAMPLE EMBODIMENTS

Hereinafter, the present invention will be clearly understood by describing specific example embodiments of the present invention with reference to the drawings.

Each example embodiment described in the present specification is merely an example, and configurations can be partially replaced or combined with each other between different example embodiments.

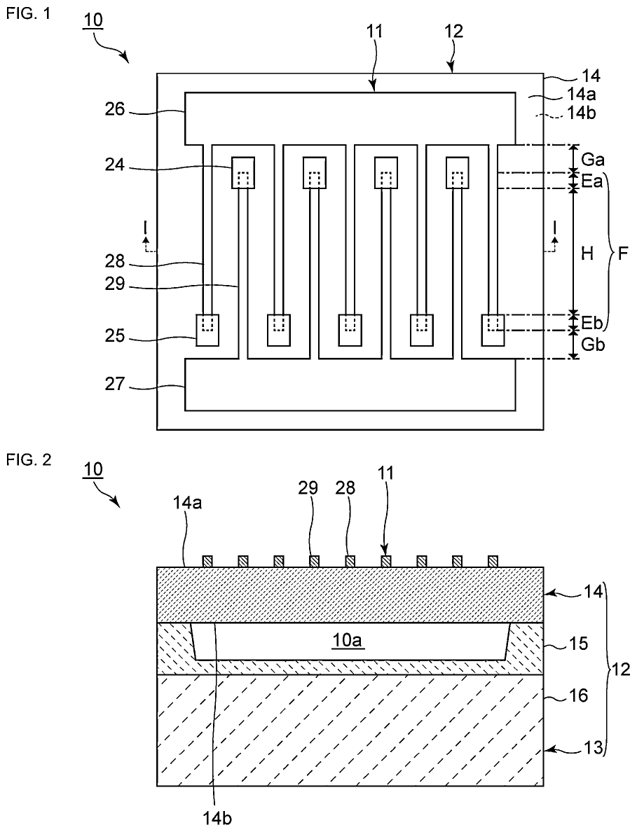

FIG. 1 is a schematic plan view of an acoustic wave device according to a first example embodiment of the present invention. FIG. 2 is a schematic cross-sectional view taken along line I-I in FIG. 1.

As shown in FIG. 1, an acoustic wave device 10 includes a piezoelectric substrate 12 and an IDT electrode 11. As shown in FIG. 2, the piezoelectric substrate 12 includes a support 13 and a piezoelectric layer 14. In the present example embodiment, the support 13 includes a support substrate 16 and an insulating layer 15. The insulating layer 15 is provided on the support substrate 16. The piezoelectric layer 14 is provided on the insulating layer 15. The support 13 may include only the support substrate 16.

The piezoelectric layer 14 has a first main surface 14a and a second main surface 14b. The first main surface 14a and the second main surface 14b face each other. Out of the first main surface 14a and the second main surface 14b, the second main surface 14b is located on the support 13 side.

As a material of the support substrate 16, for example, a semiconductor such as silicon, ceramics such as aluminum oxide, or the like can be used. As a material of the insulating layer 15, an appropriate dielectric such as silicon oxide or tantalum oxide can be used. For example, the piezoelectric layer 14 is a lithium niobate layer such as a LiNbO₃ layer or a lithium tantalate layer such as a LiTaO₃ layer. The piezoelectric layer 14 has an X-axis, a Y-axis, and a Z-axis as crystal axes.

As shown in FIG. 2, a recess is provided in the insulating layer 15. The piezoelectric layer 14 is provided on the insulating layer 15 to close the recess. In this manner, a hollow portion is formed. The hollow portion includes a cavity 10a. In the present example embodiment, the support 13 and the piezoelectric layer 14 are positioned such that a portion of the support 13 and a portion of the piezoelectric layer 14 face each other across the cavity 10a. The recess in the support 13 may be provided over the insulating layer 15 and the support substrate 16. Alternatively, the recess provided only in the support substrate 16 may be closed by the insulating layer 15. The recess may be provided in the piezoelectric layer 14. The cavity 10a may be a through hole provided in the support 13.

As shown in FIG. 1, the IDT electrode 11 includes a pair of busbars and a plurality of electrode fingers. Specifically, the pair of busbars are a first busbar 26 and a second busbar 27. The first busbar 26 and the second busbar 27 face each other. Specifically, the plurality of electrode fingers include a plurality of first electrode fingers 28 and a plurality of second electrode fingers 29. Each one end of the plurality of first electrode fingers 28 is connected to the first busbar 26. Each one end of the plurality of second electrode fingers 29 is connected to the second busbar 27. The plurality of first electrode fingers 28 and the plurality of second electrode fingers 29 are interdigitated with each other. The IDT electrode 11 may include a single metal film, or may include a laminated metal film.

Hereinafter, the first busbar 26 and the second busbar 27 may be simply referred to as a busbar. The first electrode finger 28 and the second electrode finger 29 may be simply referred to as an electrode finger. When an extending direction of the plurality of electrode fingers is defined as an electrode finger extending direction and a direction in which the electrode fingers adjacent to each other face each other is defined as an electrode finger facing direction, in the present example embodiment, the electrode finger extending direction and the electrode finger facing direction are perpendicular to each other.

When viewed in the electrode finger facing direction, a region where the adjacent electrode fingers overlap each other is an intersecting region F. The intersecting region F is a region of the piezoelectric layer 14 which is defined based on a configuration of the IDT electrode 11. The intersecting region F includes a central region H and a pair of edge regions. The pair of edge regions are disposed with the central region H interposed therebetween in the electrode finger extending direction.

Specifically, the pair of edge regions are a first edge region Ea and a second edge region Eb. The first edge region Ea is located on the first busbar 26 side. The second edge region Eb is located on the second busbar 27 side.

A region located between the intersecting region F and the pair of busbars is a pair of gap regions. Specifically, the pair of gap regions are a first gap region Ga and a second gap region Gb. The first gap region Ga is located between the first busbar 26 and the first edge region Ea. The second gap region Gb is located between the second busbar 27 and the second edge region Eb. As in the intersecting region F, each of the gap regions is a region of the piezoelectric layer 14 which is defined based on the configuration of the IDT electrode 11.

Hereinafter, the first edge region Ea and the second edge region Eb may be simply referred to as an edge region. Similarly, the first gap region Ga and the second gap region Gb may be simply referred to as a gap region. Furthermore, in the following description, when a member is provided to overlap the edge region in plan view, it may be simply said that the member is provided in the edge region. For example, even when the member is not directly provided on the piezoelectric layer 14, it may be said that the member is provided in the edge region. The same applies to the gap region.

In the present specification, description of “in plan view” means that an object is viewed in a lamination direction of the support 13 and the piezoelectric layer 14 from a direction corresponding to an upward direction in FIG. 2. In FIG. 2, for example, the piezoelectric layer 14 side of the support substrate 16 and the piezoelectric layer 14 is an upper side.

As shown in FIG. 1, a plurality of mass addition films are provided on the first main surface 14a of the piezoelectric layer 14. Specifically, the plurality of mass addition films include a plurality of first mass addition film 24 and a plurality of second mass addition films 25. More specifically, the plurality of first mass addition films 24 are provided over the first edge region Ea and the first gap region Ga. The plurality of first mass addition films 24 are aligned in the electrode finger facing direction.

In the present specification, the alignment of the plurality of mass addition films in the electrode finger facing direction means the alignment of the plurality of mass addition films in the electrode finger facing direction when viewed in the electrode finger extending direction. In the present example embodiment, in plan view, a virtual line connecting centers of the plurality of first mass addition films 24 extends parallel to the electrode finger facing direction. However, positions of the centers of the adjacent first mass addition films 24 in the electrode finger extending direction may be different from each other.

The plurality of second mass addition films 25 are provided over the second edge region Eb and the second gap region Gb. The plurality of second mass addition films 25 are aligned in the electrode finger facing direction. The plurality of first mass addition films 24 or the plurality of second mass addition films 25 may be provided. Alternatively, both the plurality of first mass addition films 24 and the plurality of second mass addition films 25 may be provided. Hereinafter, the first mass addition film 24 and the second mass addition film 25 may be simply referred to as a mass addition film.

In a configuration in which the plurality of mass addition films are aligned in the electrode finger facing direction, a period during which the plurality of mass addition films are disposed in the electrode finger facing direction is not particularly limited. For example, the electrode fingers that overlap the mass addition films in plan view may be all of the electrode fingers, or may be every other electrode finger in the electrode finger facing direction. In the present example embodiment, each of the first mass addition films 24 is provided to cover a tip portion of each of the second electrode fingers 29. Each of the second mass addition films 25 is provided to cover the tip portion of each of the first electrode fingers 28.

The plurality of first mass addition films 24 and the plurality of second mass addition films 25 are not located in at least a portion between the adjacent electrode fingers. In other words, both the first mass addition film 24 and the second mass addition film 25 are not provided in at least a portion between the adjacent electrode fingers. That is, in the first edge region Ea, at least a portion of the portion located between the electrode fingers in the piezoelectric layer 14 is exposed from the first mass addition film 24. Similarly, in the second edge region Eb, at least a portion of the portion located between the electrode fingers in the piezoelectric layer 14 is exposed from the second mass addition film 25. More specifically, in the present example embodiment, the number of the electrode fingers overlapped by each of the mass addition films in plan view is only one.

The acoustic wave device 10 of the present example embodiment is an acoustic wave resonator configured such that a bulk wave in a thickness shear mode can be used. More specifically, in the acoustic wave device 10, when the thickness of the piezoelectric layer 14 is defined as d and the center-to-center distance of the adjacent electrode fingers is defined as p, d/p is about 0.5 or smaller, for example. In this manner, the bulk wave in the thickness shear mode is suitably excited. When viewed in the electrode finger facing direction, a center-to-center region of the adjacent electrode fingers which is an overlapping region of the adjacent electrode fingers is an excitation region. In each excitation region, the bulk wave in the thickness shear mode is excited. Specifically, the excitation region is a region of the piezoelectric layer 14 which is defined based on the configuration of the IDT electrode 11.

The cavity 10a shown in FIG. 2 is an acoustic reflector in an example embodiment of the present invention. The acoustic reflector can effectively confine energy of an acoustic wave on the piezoelectric layer 14 side. The acoustic reflector may be provided at a position that overlaps at least a portion of the IDT electrode in the support in plan view. For example, an acoustic reflection film such as an acoustic multilayer film (to be described later) may be provided on a surface of the support, as the acoustic reflector.

One of the unique characteristics of the present example embodiment is that the plurality of mass addition films are not located in at least a portion between the adjacent electrode fingers. In this manner, it is possible to reduce or prevent unnecessary waves generated by providing the mass addition film. The unnecessary waves are generated in the vicinity of the resonant frequency or in the vicinity of the anti-resonant frequency. Therefore, in the present example embodiment, even when the mass addition film is provided in the edge region, the unnecessary waves can be reduced or prevented in the vicinity of the resonant frequency or in the vicinity of the anti-resonant frequency. Details of this advantageous effect will be described below by comparing the present example embodiment with a first comparative example and a second comparative example.

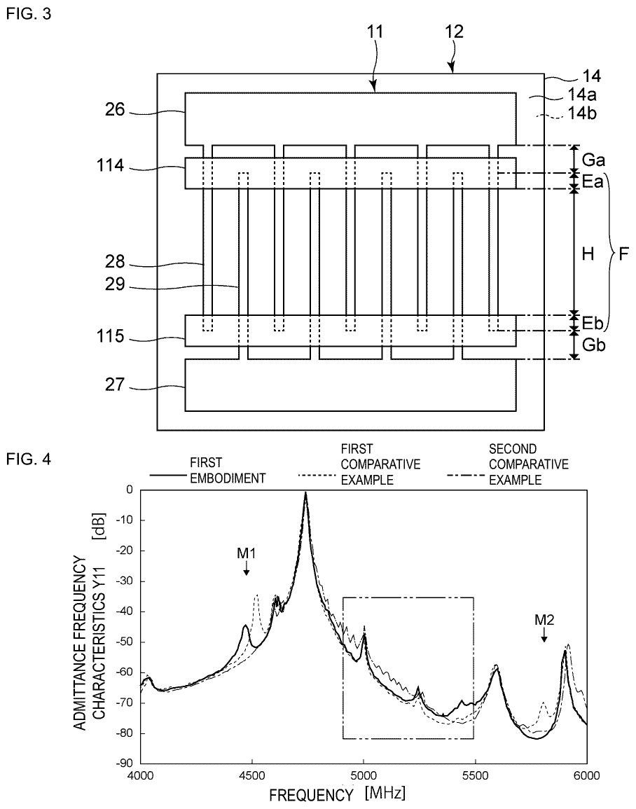

As shown in FIG. 3, the first comparative example is different from the first example embodiment in that a pair of a mass addition film 114 and a mass addition film 115 are all provided between the adjacent electrode fingers. Specifically, in the first comparative example, the mass addition film 114 is provided over the first edge region Ea and the first gap region Ga. The mass addition film 115 is provided over the second edge region Eb and the second gap region Gb. In plan view, the mass addition films are each continuously provided to overlap the plurality of electrode fingers and a region between the electrode fingers.

The second comparative example is different from the first example embodiment in that the mass addition film is not provided. Admittance frequency characteristics are measured in each of the acoustic wave device having the configuration of the first example embodiment, the acoustic wave device of the first comparative example, and the acoustic wave device of the second comparative example.

FIG. 4 is a view showing the admittance frequency characteristics in the first example embodiment, the first comparative example, and the second comparative example. When admittance in the vicinity of a frequency band surrounded by a two-dot chain line in FIG. 4 is small, a loss of the acoustic wave resonator is small. A position of the two-dot chain line is an example, and the frequency other than the two-dot chain line may have a correlation with the magnitude of the loss of the acoustic wave resonator. An arrow M1 in FIG. 4 indicates the frequency in the vicinity of the resonant frequency at which the unnecessary waves are generated. An arrow M2 indicates the frequency in the vicinity of the anti-resonant frequency at which the unnecessary waves are generated. The same applies to the drawings showing other frequency characteristics.

As shown in FIG. 4, in the first comparative example, large ripples caused by the unnecessary waves are generated in the vicinity of the frequencies indicated by the arrow M1 and the arrow M2. On the other hand, in the second comparative example, the ripples caused by the unnecessary waves are not generated in the vicinity of the frequency indicated by the arrow M1 or the arrow M2. Therefore, it can be understood that the unnecessary waves generated in the vicinity of the resonant frequency and in the vicinity of the anti-resonant frequency in the first comparative example are caused by providing the mass addition film.

On the other hand, in the first example embodiment, it can be understood that the unnecessary waves generated in the vicinity of the resonant frequency and in the vicinity of the anti-resonant frequency are reduced or prevented, compared to the first comparative example. The reason is as follows.

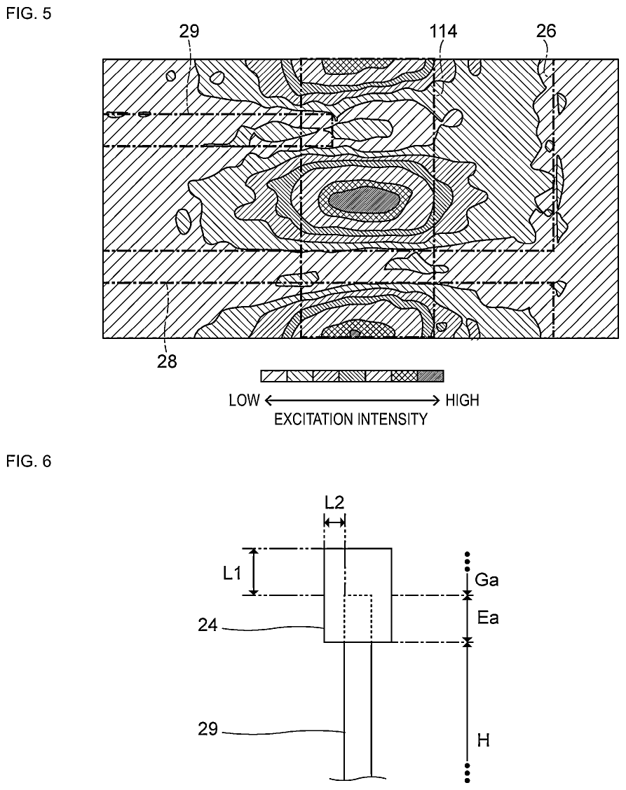

FIG. 5 is a view showing excitation intensity of the unnecessary waves in the first comparative example.

In the first comparative example, the excitation intensity of the unnecessary waves is particularly high in a region where the mass addition film is provided in the portion between the electrode fingers. On the other hand, the excitation intensity of the unnecessary waves is low in a region in which the mass addition film is laminated with the electrode finger. In the first example embodiment shown in FIG. 1, the plurality of first mass addition films 24 and the plurality of second mass addition films 25 are not located in at least a portion between the adjacent electrode fingers. In this manner, it is possible to reduce or prevent unnecessary waves generated by providing the mass addition film. That is, the unnecessary waves can be reduced or prevented in the vicinity of the resonant frequency and in the vicinity of the anti-resonant frequency.

In addition, as shown in FIG. 4, it can be understood that deterioration in the loss can be reduced or prevented in the first example embodiment, compared to the second comparative example. The reason is that the plurality of first mass addition films 24 and the plurality of second mass addition films 25 are provided in the first example embodiment. In this manner, a leakage of the acoustic waves to each busbar side can be reduced or prevented, and deterioration in the loss can be reduced or prevented.

Furthermore, a plurality of acoustic wave devices having the configuration of the first example embodiment are prepared. In the plurality of acoustic wave devices, dimensions of the first mass addition film 24 are different from each other, and dimensions of the second mass addition film 25 are different from each other. Specifically, in the plurality of acoustic wave devices, dimensions L1 of the first mass addition films 24, shown in FIG. 6, are different from each other.

More specifically, the dimension L1 is a dimension in the electrode finger extending direction of a portion located in the first gap region Ga in the first mass addition film 24. Similarly, the dimension L1 of the second mass addition film 25 is also a dimension in the electrode finger extending direction of the portion located in the second gap region Gb in the second mass addition film 25. In each of the acoustic wave devices, the dimension L1 of the first mass addition film 24 is same as the dimension L1 of the second mass addition film 25. In each of the plurality of acoustic wave devices, the dimensions L1 of the first mass addition film 24 and the second mass addition film 25 are about 1 μm, about 2 μm, about 3 μm, about 4 μm, about 5 μm, or about 7 μm, for example.

On the other hand, in the plurality of acoustic wave devices, dimensions L2 of the first mass addition films 24, shown in FIG. 6, are the same as each other. More specifically, the dimension L2 is a dimension in the electrode finger facing direction of the portion located in the region between the electrode fingers in the first mass addition film 24. The first mass addition film 24 shown in FIG. 6 is provided over a region between the electrode fingers on one side, a region overlapping the electrode finger in plan view, and a region between the electrode fingers on the other side. The dimension L2 is a dimension of a portion located in one of the two regions between the electrode fingers in the first mass addition film 24.

Similarly, the dimension L2 of the second mass addition film 25 is also a dimension in the electrode finger facing direction of the portion located in the region between the electrode fingers in the second mass addition film 25. In the plurality of acoustic wave devices, the dimensions L2 of the second mass addition films 25 are the same as each other. In the plurality of acoustic wave devices, the dimensions L2 of the first mass addition film 24 and the second mass addition film 25 are set to about 0.5 μm, for example.

In the plurality of acoustic wave devices, the thicknesses of the first mass addition films 24 are the same as each other. Similarly, in the plurality of acoustic wave devices, the thicknesses of the second mass addition films 25 are the same as each other. In the plurality of acoustic wave devices, the thicknesses of the first mass addition film 24 and the second mass addition film 25 are set to about 50 nm, for example. The admittance frequency characteristics and a return loss of the plurality of prepared acoustic wave devices are measured.

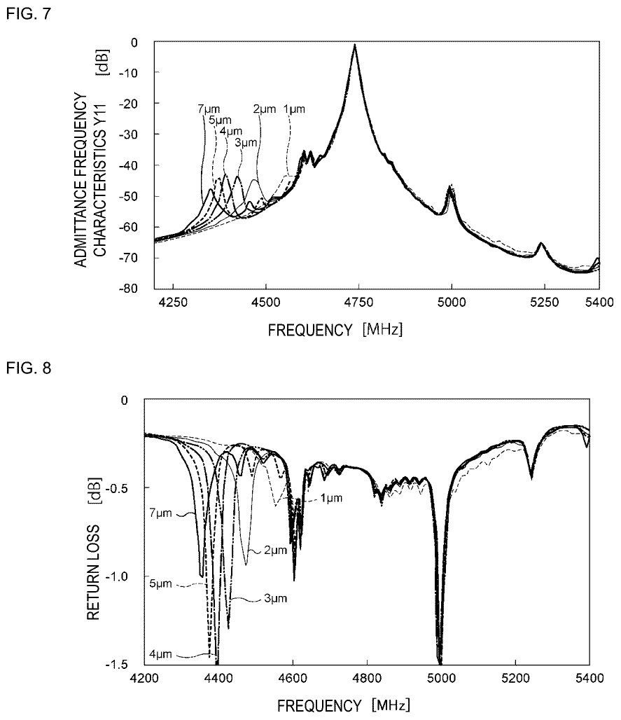

FIG. 7 is a view showing a relationship between a dimension in the electrode finger extending direction of a portion located in the gap region in the mass addition film and the admittance frequency characteristics. FIG. 8 is a view showing a relationship between a dimension in the electrode finger extending direction of a portion located in the gap region in the mass addition film and the return loss. That is, FIGS. 7 and 8 show a relationship between the dimension L1 and the admittance frequency characteristics and the return loss.

As shown in FIGS. 7 and 8, it can be understood that the frequency at which the unnecessary waves are generated is lower as the dimension in the electrode finger extending direction of the portion located in the gap region in the mass addition film increases. As the dimension increases, it can be understood that the frequency at which the unnecessary waves are generated becomes farther from the resonant frequency.

It is preferable that the dimension in the electrode finger extending direction of the portion located in the gap region in the mass addition film is about 2 μm or larger, for example. In this manner, the frequency at which the unnecessary waves are generated can effectively become farther from the resonant frequency. In this manner, when the acoustic wave device is used for the filter device, it is possible to reduce or prevent influence of the unnecessary waves on the filter characteristics. Therefore, it is possible to reduce or prevent deterioration in the filter characteristics.

Incidentally, in the first example embodiment, in a portion where the mass addition film and the electrode finger are laminated, the piezoelectric layer 14, the electrode finger, and the mass addition film are laminated in an order of the piezoelectric layer 14, the electrode finger, and the mass addition film. In the portion, the piezoelectric layer 14, the mass addition film, and the electrode finger may be laminated in an order of the piezoelectric layer 14, the mass addition film, and the electrode finger.

In plan view, the first mass addition film 24 overlaps only the second electrode finger 29 out of the first electrode finger 28 and the second electrode finger 29. In plan view, the second mass addition film 25 overlaps only the first electrode finger 28 out of the first electrode finger 28 and the second electrode finger 29. The first mass addition film 24 may overlap the first electrode finger 28 in plan view. The second mass addition film 25 may overlap the second electrode finger 29 in plan view.

Results of the first example embodiment shown in FIG. 4, FIG. 7, and FIG. 8 are results obtained when the first mass addition film 24 and the second mass addition film 25 as the mass addition films may include silicon oxide. In the present specification, a fact that a certain member includes a certain material includes a case where a trace amount of impurities is included to such an extent that electrical characteristics of the acoustic wave device do not deteriorate. The first mass addition film 24 and the second mass addition film 25 may include, for example, at least one material selected from the group consisting of silicon oxide, tantalum oxide, niobium oxide, tungsten oxide, or hafnium oxide. The materials of the first mass addition film 24 and the second mass addition film 25 are not limited to the above-described materials.

Here, the return loss when silicon oxide is used as the material of the mass addition film and the return loss when tantalum oxide is used as the material of the mass addition film are compared with each other. More specifically, the return loss when SiO₂ is used as the material of the first mass addition film 24 and the second mass addition film 25 and the return loss when Ta₂O₅ is used as the material of the first mass addition film 24 and the second mass addition film 25 are compared with each other. The return loss of the first comparative example shown in FIG. 3 is also shown together.

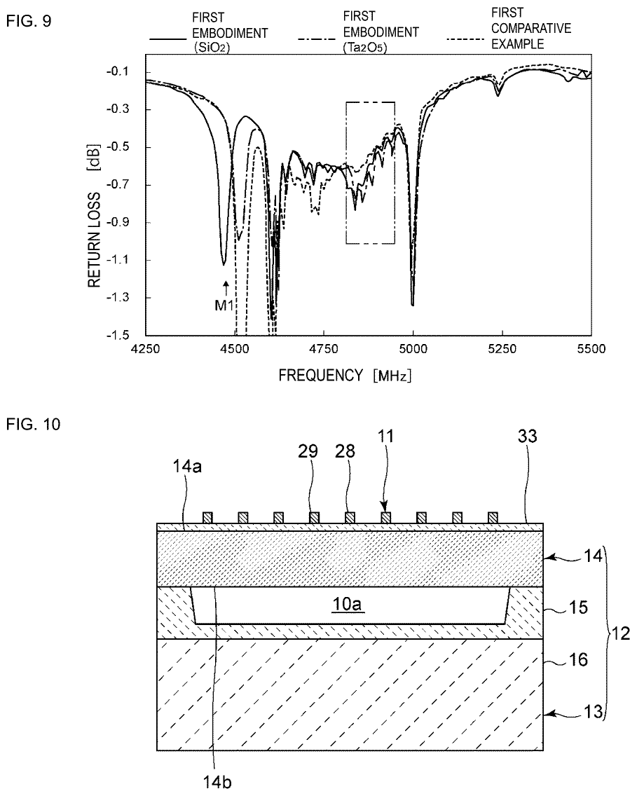

FIG. 9 is a view showing the return loss when silicon oxide is used as the material of the mass addition film in the first example embodiment, when tantalum oxide is used as the material of the mass addition film in the first example embodiment, and in the first comparative example. When the return loss in the vicinity of the frequency band surrounded by a two-dot chain line in FIG. 9 is small, the loss of the acoustic wave resonator is small. A position of the two-dot chain line is an example.

It can be understood that the unnecessary waves in the vicinity of the resonant frequency indicated by the arrow M1 in FIG. 9 are further reduced or prevented, compared to the first comparative example, regardless of whether the material of the mass addition film is silicon oxide or tantalum oxide. When the material of the mass addition film is tantalum oxide, the unnecessary waves are further reduced or prevented. On the other hand, when the material of the mass addition film is silicon oxide and when the material of the mass addition film is tantalum oxide, the magnitude of the losses is the same as each other.

In the mass addition film, it is preferable that the thickness of a portion laminated with the electrode finger is about 5 nm or larger and about 100 nm or smaller, for example. Similarly, in the mass addition film, it is preferable that the thickness of the portion which is not laminated with the electrode finger is about 5 nm or larger and about 100 nm or smaller, for example. When silicon oxide is used as the material of the mass addition film, it is more preferable that the thickness of each of the above-described portions is about 25 nm or larger and about 75 nm or smaller, for example. When tantalum oxide is used as the material of the mass addition film, it is more preferable that the thickness of each of the above-described portions is about 5 nm or larger and about 35 nm or smaller, for example.

In the first example embodiment, the dimension L2 of the first mass addition film 24 shown in FIG. 6 is not 0. The same applies to the second mass addition film 25. In the present invention, the dimension L2 of the first mass addition film 24 and the second mass addition film 25 may be 0. However, since the dimension L2 of the mass addition film is larger than 0, a transverse mode can be effectively reduced or prevented. The dimension L2 of the mass addition film may be smaller than the dimension in the electrode finger facing direction of the region between the electrode fingers.

Incidentally, as shown in FIG. 2, in the first example embodiment, the IDT electrode 11 is directly provided on the first main surface 14a of the piezoelectric layer 14. However, the present invention is not limited thereto. For example, in the modification example of the first example embodiment shown in FIG. 10, a dielectric film 33 is provided on the first main surface 14a of the piezoelectric layer 14. The IDT electrode 11 is provided on the dielectric film 33. In this case, a fractional bandwidth of the acoustic wave device can be easily adjusted by adjusting the thickness of the dielectric film 33.

As a material of the dielectric film 33, for example, silicon oxide, silicon nitride, silicon oxynitride, or the like can be used. As in the first example embodiment, in the present modification example as well, the unnecessary waves caused by providing the mass addition film can be reduced or prevented.

Therefore, the unnecessary waves can be reduced or prevented in the vicinity of the resonant frequency or in the vicinity of the anti-resonant frequency.

A configuration of the present modification example in which the IDT electrode 11 is indirectly provided on the first main surface 14a of the piezoelectric layer 14 with the dielectric film 33 interposed therebetween can be applied to a configuration other than the present modification example according to the present invention.

In the first example embodiment, the piezoelectric layer 14 includes Z-cut lithium niobate. The piezoelectric layer 14 may include rotated Y-cut lithium niobate. This example will be described with reference to a second example embodiment. The acoustic wave device of the second example embodiment has the same configuration as that of the acoustic wave device 10 of the first example embodiment, except for the material of the piezoelectric layer 14.

The admittance frequency characteristics in the acoustic wave device having the configuration of the second example embodiment and the admittance frequency characteristics in the first comparative example shown in FIG. 3 are compared. When SiO₂ is used as the material of the mass addition film and when Ta₂O₅ is used as the material of the mass addition film, the admittance frequency characteristics are compared as described above. In the comparison, the piezoelectric layer in the first comparative example includes rotated Y-cut lithium niobate.

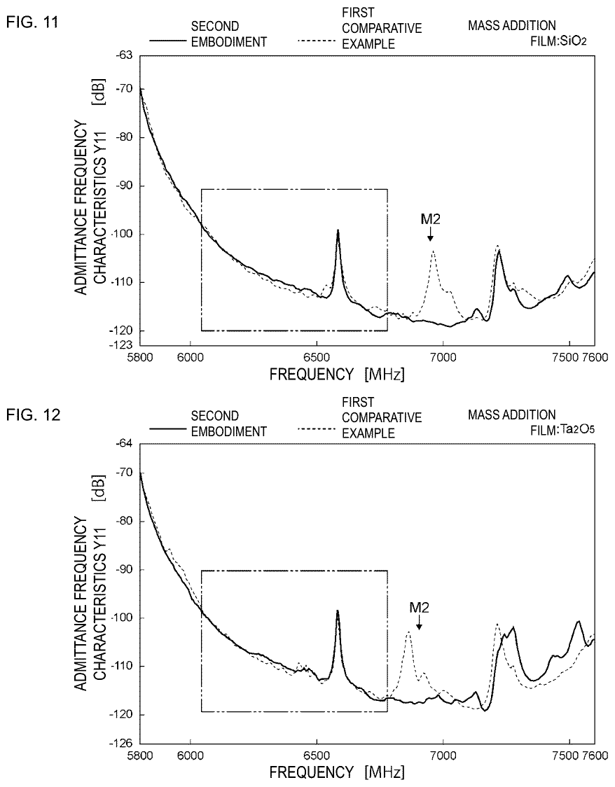

FIG. 11 is a view showing the admittance frequency characteristics when silicon oxide is used as the material of the mass addition film in the second example embodiment and the first comparative example. FIG. 12 is a view showing the admittance frequency characteristics when tantalum oxide is used as the material of the mass addition film in the second example embodiment and the first comparative example.

As shown in FIGS. 11 and 12, it can be understood that the unnecessary waves are reduced or prevented in the vicinity of the anti-resonant frequency in the second example embodiment, compared to the first comparative example.

Furthermore, the plurality of acoustic wave devices having the configuration of the second example embodiment are prepared. In the plurality of acoustic wave devices, the dimensions in the electrode finger extending direction of the gap regions are different from each other. In each of the acoustic wave devices, the dimensions in the electrode finger extending direction of the first gap region Ga and the second gap region Gb are the same as each other. In each of the plurality of acoustic wave devices, the dimensions in the electrode finger extending direction of the first gap region Ga and the second gap region Gb are set to about 0.5 μm, about 1 μm, about 1.5 μm, about 2 μm, or about 2.5 μm, for example. The admittance frequency characteristics in the plurality of acoustic wave devices are measured.

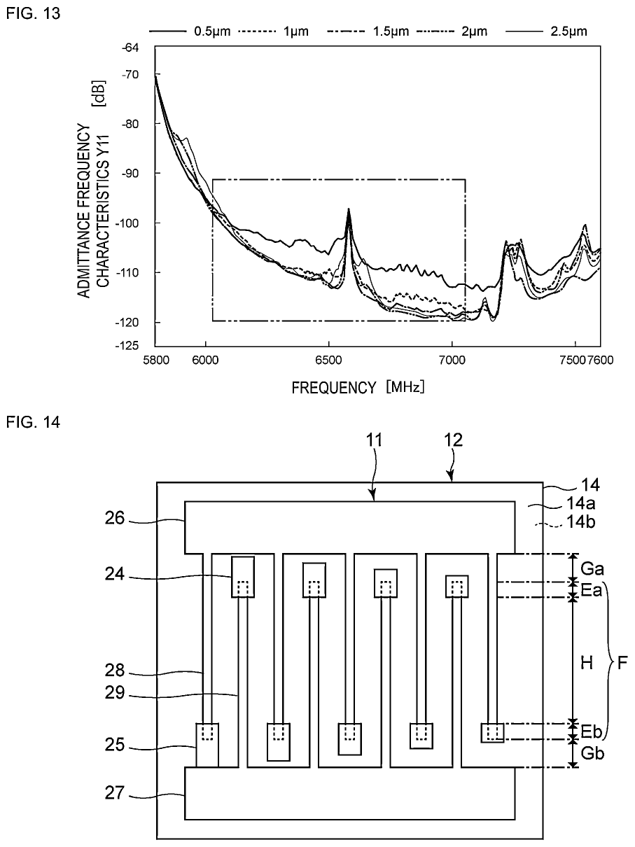

FIG. 13 is a view showing a relationship between the dimension in the electrode finger extending direction of the gap region and the admittance frequency characteristics.

As shown in FIG. 13, it can be understood that the loss decreases as the dimension in the electrode finger extending direction of the gap region increases. In particular, it can be understood that the loss decreases when the dimension in the electrode finger extending direction of the gap region is about 1 μm or larger, for example. For this reason, it is preferable that the dimension in the electrode finger extending direction of the gap region is about 1 μm or larger, for example. In this manner, deterioration in the loss can be effectively reduced or prevented.

In the first example embodiment and the second example embodiment, areas of the plurality of mass addition films in plan view are the same as each other. The plurality of mass addition films do not overlap the busbar in plan view. The present invention is not limited thereto. Hereinafter, examples in which the configuration of the mass addition film is different from that in the first example embodiment and the second example embodiment will be described with reference to a third example embodiment and a fourth example embodiment.

The acoustic wave device according to the third example embodiment and the acoustic wave device according to the fourth example embodiment have the same configurations as that of the acoustic wave device 10 according to the first example embodiment, except for the mass addition film. In the third example embodiment and the fourth example embodiment as well, as in the first example embodiment, the unnecessary waves can be reduced or prevented by providing the mass addition film. Therefore, the unnecessary waves can be reduced or prevented in the vicinity of the resonant frequency or in the vicinity of the anti-resonant frequency.

FIG. 14 is a schematic plan view of the acoustic wave device according to the third example embodiment.

In the present example embodiment, the dimensions in the electrode finger extending direction of the plurality of first mass addition films 24 are different from each other. Therefore, areas of the plurality of first mass addition films 24 in plan view are different from each other. Similarly, the dimensions in the electrode finger extending direction of the plurality of second mass addition films 25 are different from each other. Therefore, areas of the plurality of second mass addition films 25 in plan view are different from each other.

The plurality of first mass addition films 24 may include at least one first mass addition film 24 having a different area in plan view. Similarly, the plurality of second mass addition films 25 may include at least one second mass addition film 25 having a different area in plan view.

In the present example embodiment, the frequency of the generated unnecessary waves varies depending on each mass addition film. In this way, since the frequency of the unnecessary waves can vary, the unnecessary waves can be reduced or prevented as a whole.

In a case of the acoustic wave device using the surface acoustic wave, the surface acoustic wave is excited by the plurality of electrode fingers as a whole. In contrast, in a case of the acoustic wave device using the bulk wave in the thickness shear mode, a portion where a pair of the first electrode finger 28 and the second electrode finger 29 are provided on the piezoelectric layer 14 functions as one resonator. The configuration of the acoustic wave device corresponds to a configuration in which a plurality of resonators are connected in parallel. Therefore, in example embodiments of the present invention, even when the areas of the mass addition films are not uniform, a waveform in the frequency characteristics is less likely to be broken. That is, the unnecessary waves can be reduced or prevented without deteriorating the electrical characteristics.

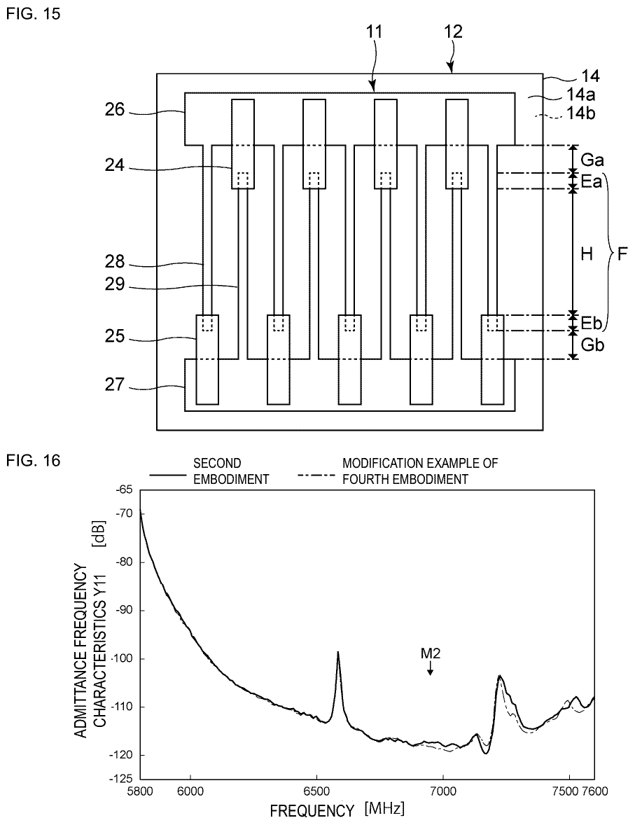

FIG. 15 is a schematic plan view of the acoustic wave device according to the fourth example embodiment.

In the present example embodiment, the plurality of first mass addition films 24 extend from the first gap region Ga to a portion overlapping the first busbar 26 in plan view. More specifically, the plurality of first mass addition films 24 are provided over the first edge region Ea, the first gap region Ga, and a region where the first busbar 26 is provided. Similarly, the plurality of second mass addition films 25 overlap the second busbar 27 in plan view.

In the present example embodiment, the piezoelectric layer 14, the busbar, and the mass addition film are laminated in an order of the piezoelectric layer 14, the busbar, and the mass addition film. The piezoelectric layer 14, the mass addition film, and the busbar may be laminated in an order of the piezoelectric layer 14, the mass addition film, and the busbar.

In the third example embodiment and the fourth example embodiment, Z-cut lithium niobate is used as the material of the piezoelectric layer 14. The rotated Y-cut lithium niobate may be used as the material of the piezoelectric layer 14. Alternatively, lithium tantalate may be used as the material of the piezoelectric layer 14.

Here, the acoustic wave device having a configuration of a modification example of the fourth example embodiment is prepared, which is different from the fourth example embodiment only in that the piezoelectric layer 14 includes rotated Y-cut lithium niobate. Furthermore, the acoustic wave device having a configuration of the second example embodiment is prepared. The admittance frequency characteristics are measured.

FIG. 16 is a view showing the admittance frequency characteristics in the second example embodiment and the modification example of the fourth example embodiment.

As shown in FIG. 16, as in the second example embodiment, in the modification example of the fourth example embodiment, the unnecessary waves can be reduced or prevented in the vicinity of the anti-resonant frequency. In this way, it can be understood that an advantageous effect of reducing or preventing the unnecessary waves is not significantly different depending on whether or not the mass addition film overlaps the busbar in plan view.

For example, during manufacturing of the acoustic wave device, a position of the mass addition film may deviate due to misalignment when the mass addition film is provided. In the fourth example embodiment and the modification example thereof, the mass addition film overlaps the busbar in plan view. In addition, in any of the fourth example embodiment and the modification example thereof, the unnecessary waves caused by the mass addition film can be reduced or prevented. In this way, even when the position of the mass addition films deviates, the influence is small. Therefore, with example embodiments of the present invention, it is possible to reduce the influence of the misalignment caused during manufacture.

In the first to fourth example embodiments, the mass addition film is laminated with the tip portion of the electrode finger. In the portion where the mass addition film and the electrode finger are laminated, the piezoelectric layer 14, the electrode finger, and the mass addition film are laminated in this order. The present invention is not limited thereto. Hereinafter, examples in which the configuration of the mass addition film is different from that of the first to fourth example embodiments will be described with reference to fifth to seventh example embodiments.

The acoustic wave device of the fifth to seventh example embodiments has the same configuration as that of the acoustic wave device 10 of the first example embodiment, except for the mass addition film. As in the first example embodiment, in the fifth to seventh example embodiments as well, the unnecessary waves can be reduced or prevented by providing the mass addition film. Therefore, the unnecessary waves can be reduced or prevented in the vicinity of the resonant frequency or in the vicinity of the anti-resonant frequency.

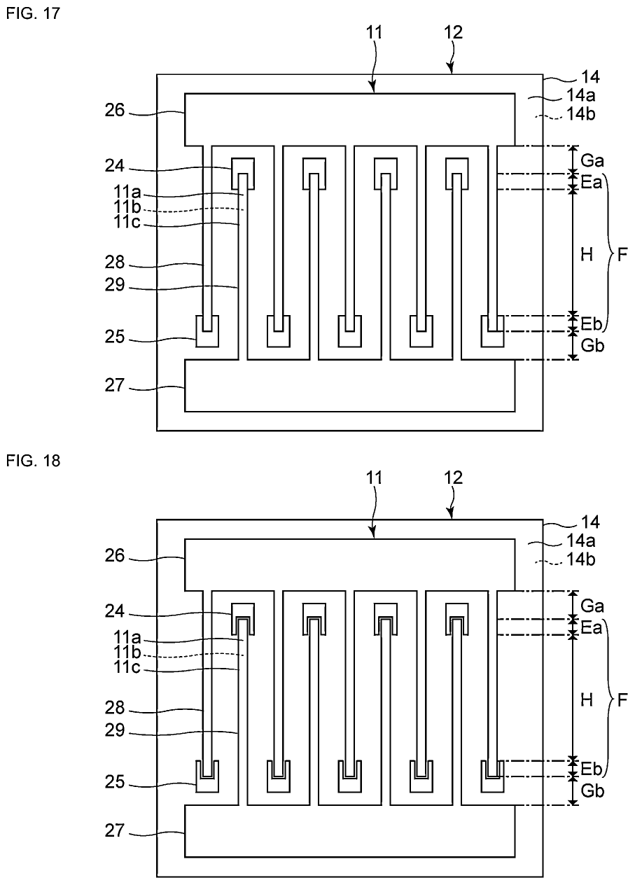

FIG. 17 is a schematic plan view of the acoustic wave device according to the fifth example embodiment.

In the present example embodiment, the first mass addition film 24 surrounds the tip portion of the second electrode finger 29 in three directions in plan view. The first mass addition film 24 is in contact with the second electrode finger 29. In plan view, the first mass addition film 24 does not overlap the second electrode finger 29. A shape of the first mass addition film 24 in plan view is a U-shape.

More specifically, the plurality of electrode fingers have a first surface 11a, a second surface 11b, and a side surface 11c. The first surface 11a and the second surface 11b face each other in a thickness direction. Out of the first surface 11a and the second surface 11b, the second surface 11b is a surface on the piezoelectric layer 14 side. The side surface 11c is connected to the first surface 11a and the second surface 11b. The first mass addition film 24 is in contact with the side surface 11c of the second electrode finger 29.

Similarly, the second mass addition film 25 surrounds the tip portion of the first electrode finger 28 in three directions in plan view. The second mass addition film 25 is in contact with the side surface 11c of the first electrode finger 28. In plan view, the second mass addition film 25 does not overlap the first electrode finger 28. A shape of the second mass addition film 25 in plan view is a U-shape.

The plurality of mass addition films may include at least one mass addition film that surrounds the tip portion of the electrode finger in three directions in plan view.

In the present example embodiment, the mass addition film does not overlap the tip portion of the electrode finger in plan view. In this manner, mass addition in the tip portion of the electrode finger decreases.

In this manner, electric power handling capability of the acoustic wave device can be improved.

FIG. 18 is a schematic plan view of the acoustic wave device according to the sixth example embodiment.

In the present example embodiment, the first mass addition film 24 surrounds the tip portion of the second electrode finger 29 in three directions in plan view. The first mass addition film 24 is not in contact with the second electrode finger 29. In plan view, the first mass addition film 24 does not overlap the second electrode finger 29.

Similarly, the second mass addition film 25 surrounds the tip portion of the first electrode finger 28 in three directions in plan view. The second mass addition film 25 is not in contact with the side surface of the first electrode finger 28. In plan view, the second mass addition film 25 does not overlap the first electrode finger 28.

As in the fifth example embodiment, in the present example embodiment as well, electric power handling capability of the acoustic wave device can be improved.

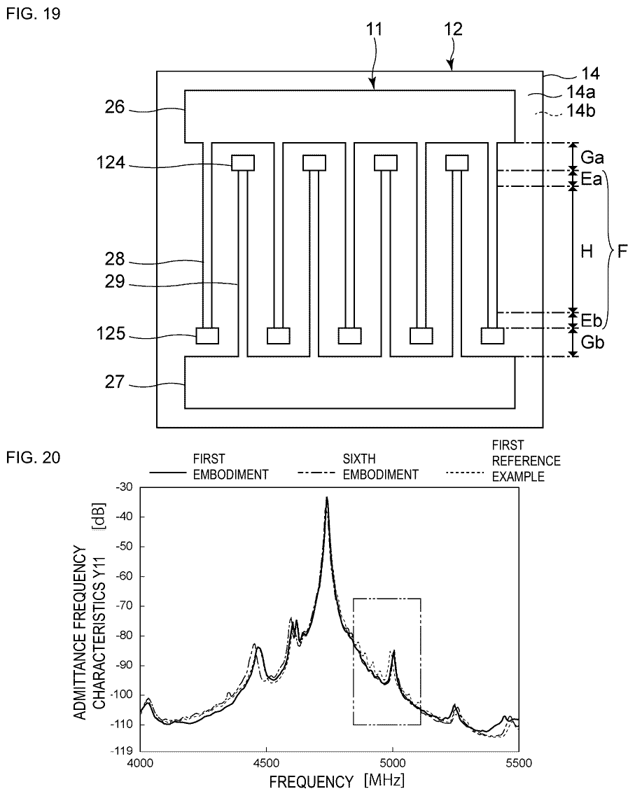

Here, the admittance frequency characteristics are compared among the first example embodiment, the sixth example embodiment, and a first reference example. As shown in FIG. 19, the first reference example is different from the first example embodiment in that a mass addition film 124 and a mass addition film 125 are not provided in the edge region. In the first reference example, as in the first example embodiment, the mass addition film 124 and the mass addition film 125 are provided in the gap region.

FIG. 20 is a view showing the admittance frequency characteristics in the first example embodiment, the sixth example embodiment, and the first reference example.

As shown in FIG. 20, in the first example embodiment, the sixth example embodiment, and the first reference example, the unnecessary waves are reduced or prevented in the vicinity of the resonant frequency. Furthermore, in the first example embodiment and the sixth example embodiment, it can be understood that the loss is smaller than in the first reference example. In this way, in the first example embodiment and the sixth example embodiment, since the mass addition film is provided in the edge region, deterioration in the loss can be reduced or prevented.

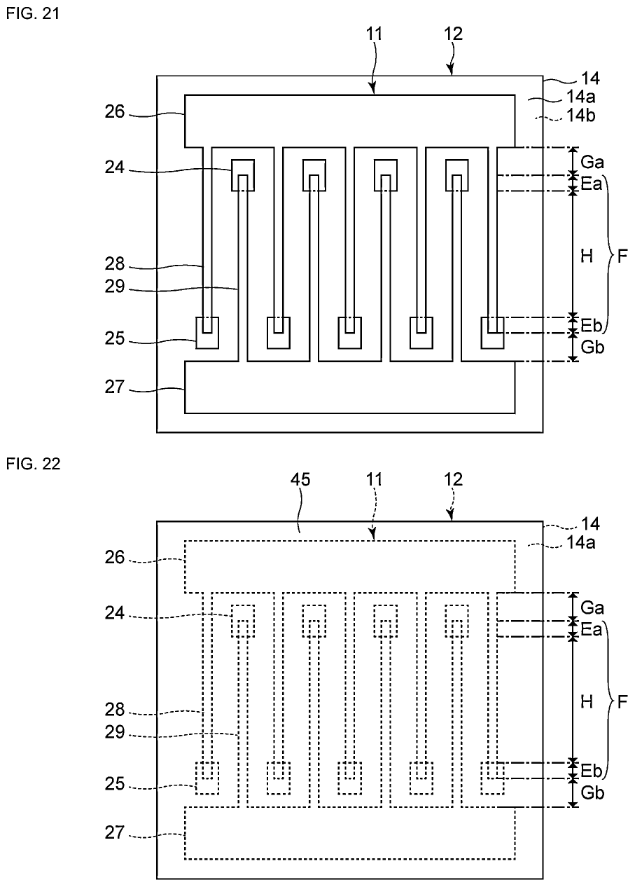

FIG. 21 is a schematic plan view of the acoustic wave device according to the seventh example embodiment.

In the present example embodiment, the first mass addition film 24 overlaps the tip portion of the second electrode finger 29 in plan view. More specifically, in the portion where the first mass addition film 24 and the second electrode finger 29 are laminated, the piezoelectric layer 14, the first mass addition film 24, and the second electrode finger 29 are laminated in an order of the piezoelectric layer 14, the first mass addition film 24, and the second electrode finger 29.

Similarly, the second mass addition film 25 overlaps the tip portion of the first electrode finger 28 in plan view. More specifically, in the portion where the second mass addition film 25 and the first electrode finger 28 are laminated, the piezoelectric layer 14, the second mass addition film 25, and the first electrode finger 28 are laminated in this order.

In the present example embodiment, the mass addition film is provided between the piezoelectric layer 14 and the tip portion of the electrode finger. In this manner, an electric field applied to the electrode finger is reduced or prevented. In this manner, electric power handling capability of the acoustic wave device can be improved.

In the fifth to seventh example embodiments, as in the first example embodiment, Z-cut lithium niobate is used as the material of the piezoelectric layer 14. The rotated Y-cut lithium niobate may be used as the material of the piezoelectric layer 14. Alternatively, lithium tantalate may be used as the material of the piezoelectric layer 14.

FIG. 22 is a schematic plan view of an acoustic wave device according to an eighth example embodiment.

The present example embodiment is different from the first example embodiment in that a dielectric film 45 is provided on the piezoelectric layer 14. The dielectric film 45 covers the IDT electrode 11 and the plurality of mass addition films. Therefore, in the portion where the mass addition film and the dielectric film 45 are laminated, the piezoelectric layer 14, the mass addition film, and the dielectric film 45 are laminated in an order of the piezoelectric layer 14, the mass addition film, and the dielectric film 45. The acoustic wave device of the present example embodiment has the same configuration as that of the acoustic wave device 10 of the first example embodiment, except for the above-described points.

The IDT electrode 11 is protected by the dielectric film 45. In this manner, the IDT electrode 11 is less likely to be damaged. The frequency can be easily adjusted by adjusting the thickness of the dielectric film 45. In addition, as in the first example embodiment, in the present example embodiment as well, the unnecessary waves generated by providing the mass addition film can be reduced or prevented. Therefore, the unnecessary waves can be reduced or prevented in the vicinity of the resonant frequency or in the vicinity of the anti-resonant frequency.

As the dielectric film 45, for example, silicon oxide, silicon nitride, silicon oxynitride, or the like can be used. The material of the dielectric film 45 is not limited to the above-described material.

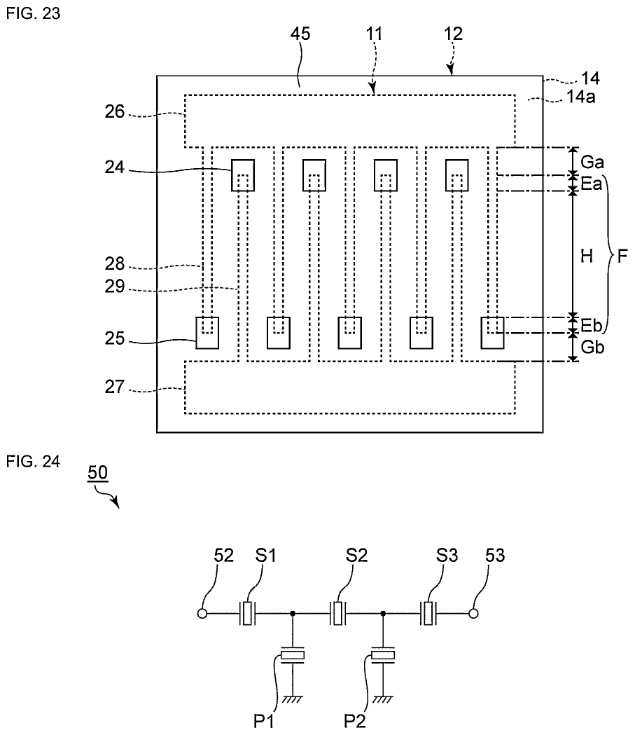

The order of laminating the mass addition film and the dielectric film 45 is not limited to the above-described order. For example, in a modification example of the eighth example embodiment shown in FIG. 23, in the portion where the mass addition film and the dielectric film 45 are laminated, the piezoelectric layer 14, the dielectric film 45, and the mass addition film are laminated in an order of the piezoelectric layer 14, the dielectric film 45, and the mass addition film. In this case as well, as in the eighth example embodiment, the unnecessary waves can be reduced or prevented in the vicinity of the resonant frequency or in the vicinity of the anti-resonant frequency.

In the eighth example embodiment and the modification example thereof, as in the first example embodiment, Z-cut lithium niobate is used as the material of the piezoelectric layer 14. The rotated Y-cut lithium niobate may be used as the material of the piezoelectric layer 14. Alternatively, lithium tantalate may be used as the material of the piezoelectric layer 14.

An acoustic wave device according to an example embodiment of the present invention can be used for the filter device, for example. This example will be described below.

FIG. 24 is a circuit diagram of a filter device according to a ninth example embodiment of the present invention.

A filter device 50 is a ladder filter. The filter device 50 includes a first signal terminal 52, a second signal terminal 53, a plurality of series arm resonators, and a plurality of parallel arm resonators. In the present example embodiment, all of the series arm resonators and all of the parallel arm resonators are acoustic wave resonators. All of the acoustic wave resonators are the acoustic wave devices according to example embodiments of the present invention. At least one acoustic wave resonator in the filter device 50 may be an acoustic wave device according to an example embodiment of the present invention.

For example, the first signal terminal 52 and the second signal terminal 53 may be configured as an electrode pad, or may be configured as wiring. In the present example embodiment, the second signal terminal 53 is an antenna terminal. The antenna terminal is connected to an antenna.

Specifically, the plurality of series arm resonators of the filter device 50 are a series arm resonator S1, a series arm resonator S2, and a series arm resonator S3. Specifically, the plurality of parallel arm resonators are a parallel arm resonator P1 and a parallel arm resonator P2.

The series arm resonator S1, the series arm resonator S2, and the series arm resonator S3 are connected in series to each other between the first signal terminal 52 and the second signal terminal 53. The parallel arm resonator P1 is connected between a connection point of the series arm resonator S1 and the series arm resonator S2, and a ground potential. The parallel arm resonator P2 is connected between a connection point of the series arm resonator S2 and the series arm resonator S3, and the ground potential. A circuit configuration of the filter device 50 is not limited to the above-described example. When the filter device 50 according to an example embodiment of the present invention is a ladder filter, the filter device 50 may include at least one series arm resonator and at least one parallel arm resonator.

Alternatively, for example, the filter device 50 may include a longitudinally coupled resonator-type acoustic wave filter. In this case, for example, the filter device 50 may include the series arm resonator or the parallel arm resonator connected to the longitudinally coupled resonator-type acoustic wave filter. The series arm resonator or the parallel arm resonator may be an acoustic wave device according to an example embodiment of the present invention.

In the present example embodiment, all of the acoustic wave resonators share the piezoelectric substrate. For example, the piezoelectric layer in the piezoelectric substrate may include Z-cut lithium niobate, or may include rotated Y-cut lithium niobate. Alternatively, the piezoelectric layer may include lithium tantalate. Each of the acoustic wave resonators may include an individual piezoelectric substrate.

The anti-resonant frequency of the parallel arm resonator defining a pass band of the filter device 50 is located inside the pass band of the filter device 50. Therefore, the influence of the unnecessary waves generated in the vicinity of the anti-resonant frequency in the parallel arm resonator is great on electrical characteristics inside the pass band in the filter device 50. The resonant frequency of the series arm resonator forming the pass band of the filter device 50 is located inside the pass band of the filter device 50.

Therefore, the influence of the unnecessary waves generated in the vicinity of the resonant frequency in the series arm resonator is also great on the electrical characteristics inside the pass band in the filter device 50.

In the present example embodiment, each of the parallel arm resonators and each of the series arm resonators are an acoustic wave device according to an example embodiment of the present invention. For example, the acoustic wave device which can reduce or prevent the unnecessary waves in the vicinity of the anti-resonant frequency may be used for each of the parallel arm resonators. For example, the acoustic wave device which can reduce or prevent the unnecessary waves in the vicinity of the resonant frequency may be used for each of the series arm resonators. In this manner, it is possible to reduce or prevent the influence of the unnecessary waves on the electrical characteristics inside the pass band of the filter device 50. In addition, when the acoustic wave device of the first example embodiment or the like is used as the series arm resonator or the parallel arm resonator, it is possible to reduce or prevent deterioration in the loss in the acoustic wave resonator. Therefore, deterioration in the filter characteristics of the filter device 50 can be reduced or prevented.

Here, in the series arm resonators of the filter device 50, the series arm resonator which is the acoustic wave device according to an example embodiment of the present invention is referred to as a first acoustic wave resonator. In the parallel arm resonators of the filter device 50, the parallel arm resonator which is the acoustic wave device according to an example embodiment of the present invention is referred to as a second acoustic wave resonator. It is preferable that the filter device 50 includes at least one first acoustic wave resonator and at least one second acoustic wave resonator. In this manner, deterioration in the filter characteristics can be more reliably reduced or prevented.

In the present example embodiment, the thickness of the plurality of mass addition films of the second acoustic wave resonator is smaller than the thickness of the plurality of mass addition films of the first acoustic wave resonator. When the thickness of the mass addition film is smaller, the unnecessary waves caused by the mass addition film in the vicinity of the anti-resonant frequency are reduced or prevented. Therefore, in the present example embodiment, deterioration in the filter characteristics can be effectively reduced or prevented.

For example, when the unnecessary waves are generated at a frequency on a high band side in the parallel arm resonator, the influence on the filter characteristics is greater than that when the unnecessary waves are generated at a frequency on a high band side in the series arm resonator. In contrast, in the present example embodiment, an average value of areas of the plurality of mass addition films of the second acoustic wave resonator in plan view is greater than an average value of areas of the plurality of mass addition films of the first acoustic wave resonator in plan view. When the area of the mass addition film is large, the unnecessary waves generated at the frequency on the high band side are reduced or prevented. Therefore, in the present example embodiment, deterioration in the filter characteristics can be further reduced or prevented.

FIG. 25 is a circuit diagram of a filter device according to a tenth example embodiment.

A filter device 60 is a ladder filter. The present example embodiment is different from the ninth example embodiment in the circuit configuration and the configuration of each acoustic wave resonator.

Specifically, the plurality of series arm resonators of the filter device 60 are a series arm resonator S11, a series arm resonator S12, a series arm resonator S13, and a series arm resonator S14. Specifically, the plurality of parallel arm resonators are a parallel arm resonator P11, a parallel arm resonator P12, and a parallel arm resonator P13.

The series arm resonators S11, S12, S13, and S14 are connected in series to each other between the first signal terminal 52 and the second signal terminal 53. The parallel arm resonator P11 is connected between a connection point of the series arm resonator S11 and the series arm resonator S12, and the ground potential. The parallel arm resonator P12 is connected between a connection point of the series arm resonator S12 and the series arm resonator S13, and the ground potential. The parallel arm resonator P13 is connected between a connection point of the series arm resonator S13 and the series arm resonator S14, and the ground potential.

In the present example embodiment, all of the acoustic wave resonators share the piezoelectric substrate. More specifically, the piezoelectric layer of the piezoelectric substrate in the present example embodiment includes rotated Y-cut lithium niobate.

Here, the acoustic wave resonator which includes the piezoelectric layer including rotated Y-cut lithium niobate and which is an acoustic wave device according to an example embodiment of the present invention is referred to as a third acoustic wave resonator. In the present example embodiment, the third acoustic wave resonator is the acoustic wave device according to the second example embodiment. In the filter device 60, all of the parallel arm resonators are the third acoustic wave resonator.

In each of the third acoustic wave resonators of the filter device 60, as shown with reference to FIG. 1, the first mass addition film 24 is provided over the first edge region Ea and the first gap region Ga. In the present example embodiment, the first mass addition film 24 is provided in the whole first gap region Ga in the electrode finger extending direction. Therefore, the dimension in the electrode finger extending direction of the portion provided in the first gap region Ga in the first mass addition film 24 is the same as the dimension in the electrode finger extending direction of the first gap region Ga.

Similarly, the second mass addition film 25 is provided over the second edge region Eb and the second gap region Gb. The dimension in the electrode finger extending direction of the portion provided in the second gap region Gb in the second mass addition film 25 is the same as the dimension in the electrode finger extending direction of the second gap region Gb. Each of the mass addition films may be provided in a portion of each of the gap regions in the electrode finger extending direction.

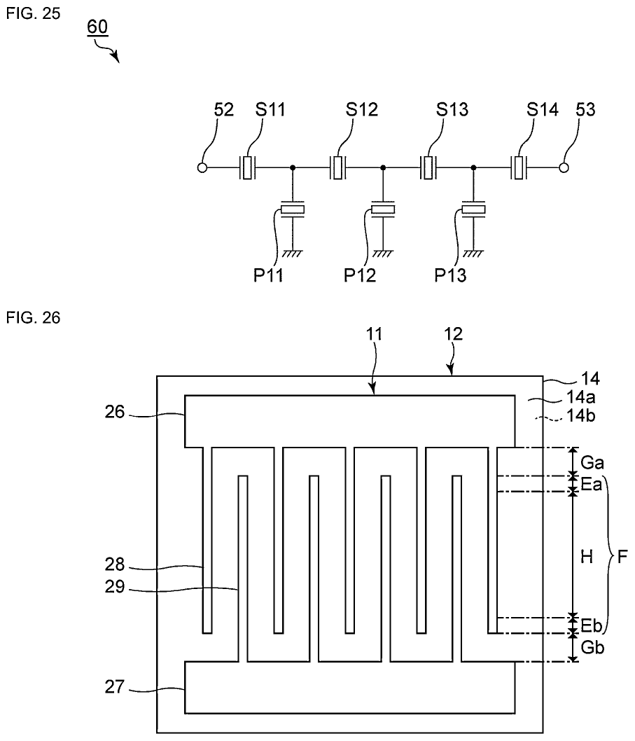

On the other hand, the acoustic wave resonator which includes the piezoelectric layer including rotated Y-cut lithium niobate and which is the acoustic wave device having no mass addition film is referred to as a fourth acoustic wave resonator. As shown in FIG. 26, as in the third acoustic wave resonator, the fourth acoustic wave resonator includes the IDT electrode 11. In the filter device 60, all of the series arm resonators are the fourth acoustic wave resonator. In the present example embodiment, the dimension in the electrode finger extending direction of the gap region in the third acoustic wave resonator is larger than the dimension in the electrode finger extending direction of the gap region in the fourth acoustic wave resonator.

A single third acoustic wave resonator and a single fourth acoustic wave resonator are each prepared, and the admittance frequency characteristics are measured.

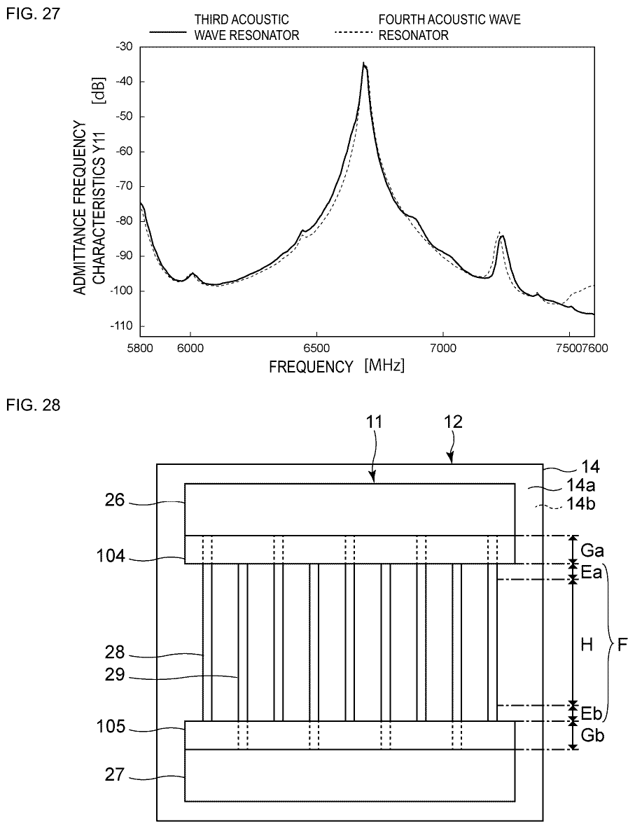

FIG. 27 is a view showing the admittance frequency characteristics of the third acoustic wave resonator and the fourth acoustic wave resonator in the tenth example embodiment.

The third acoustic wave resonator is the acoustic wave device according to the second example embodiment, and as shown in FIG. 27, the unnecessary waves are reduced or prevented in the vicinity of the resonant frequency. Furthermore, in the third acoustic wave resonator, the unnecessary waves are reduced or prevented in the vicinity of about 7000 MHz, and the loss including the frequency on the high band side in the vicinity of about 7600 MHz is small, for example. The reason is that the third acoustic wave resonator has a large dimension in the electrode finger extending direction in the gap region. More specifically, as shown in FIG. 13, in the third acoustic wave resonator, deterioration in the loss can be reduced or prevented as the dimension in the electrode finger extending direction of the gap region increases.

As in the present example embodiment, when the third acoustic wave resonator is used for the filter device, it is preferable to use the third acoustic wave resonator as the parallel arm resonator. When the loss of the frequency on the high band side in the parallel arm resonator is large, the influence on the filter characteristics is greater than that when the loss of the frequency on the high band side in the series arm resonator is large. When the third parallel arm resonator is used as the parallel arm resonator, the loss of the frequency on the high band side in the parallel arm resonator can be reduced or prevented. In this manner, the filter characteristics can be improved.

It is preferable that the dimension in the electrode finger extending direction of the gap region in the third acoustic wave resonator used as the parallel arm resonator is larger than the dimension in the electrode finger extending direction of the gap region in the fourth acoustic wave resonator used as the series arm resonator. In this manner, the deterioration in the loss of the third acoustic wave resonator can be more reliably reduced or prevented. Therefore, the filter characteristics in the filter device 60 can be more reliably improved.

Since the fourth acoustic wave resonator does not include the mass addition film, the unnecessary waves caused by the mass addition film are not generated. Therefore, as shown in FIG. 27, intensity of the unnecessary waves in the vicinity of the resonant frequency is low.

In addition, in the fourth acoustic wave resonator, the loss does not particularly deteriorate, except for the frequency on the high band side in the vicinity of about 7600 MHZ, for example. The reason is that rotated Y-cut lithium niobate is used for the piezoelectric layer of the fourth acoustic wave resonator. Furthermore, in the fourth acoustic wave resonator, the mass addition film is not provided. More specifically, the reason is that the mass addition film does not overlap the tip of the electrode finger in plan view. Since the fourth acoustic wave resonator is used as the series arm resonator, the filter characteristics of the filter device 60 are less likely to deteriorate.

For example, at least one of the parallel arm resonators may be the third acoustic wave resonator, and at least one of the series arm resonators may be the fourth acoustic wave resonator. In this case as well, in the third acoustic wave resonator of the filter device 60, the unnecessary waves can be reduced or prevented in the vicinity of the resonant frequency or in the vicinity of the anti-resonant frequency. In addition, deterioration in the filter characteristics of the filter device 60 can be reduced or prevented.

It is preferable that all of the fourth acoustic wave resonators are the series arm resonators. In this case, deterioration in the filter characteristic of the filter device 60 can be more reliably reduced or prevented.

Hereinafter, an eleventh example embodiment and a twelfth example embodiment in which only the configuration of each acoustic wave resonator is different from the configuration of the acoustic wave resonator of the tenth example embodiment will be described. In the eleventh example embodiment and the twelfth example embodiment, all of the acoustic wave resonators share the piezoelectric substrate. However, each acoustic wave resonator may have an individual piezoelectric substrate.

In the eleventh example embodiment, as in the tenth example embodiment, all of the parallel arm resonators are the third acoustic wave resonators. On the other hand, all of the series arm resonators are fifth acoustic wave resonators.

In the third acoustic wave resonator which is an acoustic wave device according to an example embodiment of the present invention, the unnecessary waves can be reduced or prevented in the vicinity of the resonant frequency or in the vicinity of the anti-resonant frequency. In addition, deterioration in the loss at the frequency on the high band side can be reduced or prevented. In the eleventh example embodiment as well, as in the tenth example embodiment, the third acoustic wave resonator is used as the parallel arm resonator. In this manner, deterioration in the filter characteristics of the filter device according to the eleventh example embodiment can be reduced or prevented.

Hereinafter, the fifth acoustic wave resonator will be described.

FIG. 28 is a schematic plan view of the fifth acoustic wave resonator in the eleventh example embodiment.

In the fifth acoustic wave resonator, the piezoelectric layer 14 of the piezoelectric substrate 12 includes rotated Y-cut lithium niobate. The fifth acoustic wave resonator includes the IDT electrode 11, and a pair of a mass addition film 104 and a mass addition film 105. The mass addition film 104 and the mass addition film 105 have a strip shape.

The mass addition film 104 is provided in the first gap region Ga, and is not provided in the intersecting region F. The mass addition film 104 is continuously provided to overlap the plurality of electrode fingers and a region between the electrode fingers in plan view.

In the eleventh example embodiment, the mass addition film 104 is provided in the whole first gap region Ga in the electrode finger extending direction. Therefore, the dimension in the electrode finger extending direction of the mass addition film 104 is the same as the dimension in the electrode finger extending direction of the first gap region Ga.

Similarly, the mass addition film 105 is provided in the second gap region Gb, and is not provided in the intersecting region F. The mass addition film 105 is continuously provided to overlap the plurality of electrode fingers and a region between the electrode fingers in plan view. The dimension in the electrode finger extending direction of the mass addition film 105 is the same as the dimension in the electrode finger extending direction of the second gap region Gb.

In the fifth acoustic wave resonator, each mass addition film may be provided in a portion of each gap region in the electrode finger extending direction. Alternatively, in the fifth acoustic wave resonator, at least one of the mass addition film 104 and the mass addition film 105 may overlap the busbar in plan view. In the fifth acoustic wave resonator, the mass addition film may be provided in at least one of the first gap region Ga and the second gap region Gb.

A single fifth acoustic wave resonator is prepared, and the admittance frequency characteristics are measured. Furthermore, the influence of positional deviation of the mass addition film on the admittance frequency characteristics is examined. Specifically, the acoustic wave resonators of the second reference example and the third reference example are prepared, and the admittance frequency characteristics of each acoustic wave resonator are measured. The positional deviation is caused by misalignment or the like when the mass addition film is provided.

In the acoustic wave resonator of the second reference example, each mass addition film is provided in the whole gap region and a portion of the edge region. More specifically, in the acoustic wave resonator, the mass addition film is continuously provided in a portion of the edge region such to overlap the plurality of electrode fingers and the region between the electrode fingers in plan view. More specifically, the dimension in the electrode finger extending direction of the mass addition film in the acoustic wave resonator is about 150 nm larger than the dimension in the electrode finger extending direction of the gap region, for example.

In the acoustic wave resonator of the third reference example, the mass addition film is provided in a portion of the gap region in the electrode finger extending direction. More specifically, in the acoustic wave resonator, the mass addition film is in contact with the tip of the electrode finger, and is not in contact with the busbar. More specifically, the dimension in the electrode finger extending direction of the mass addition film in the acoustic wave resonator is about 150 nm smaller than the dimension in the electrode finger extending direction of the gap region, for example.

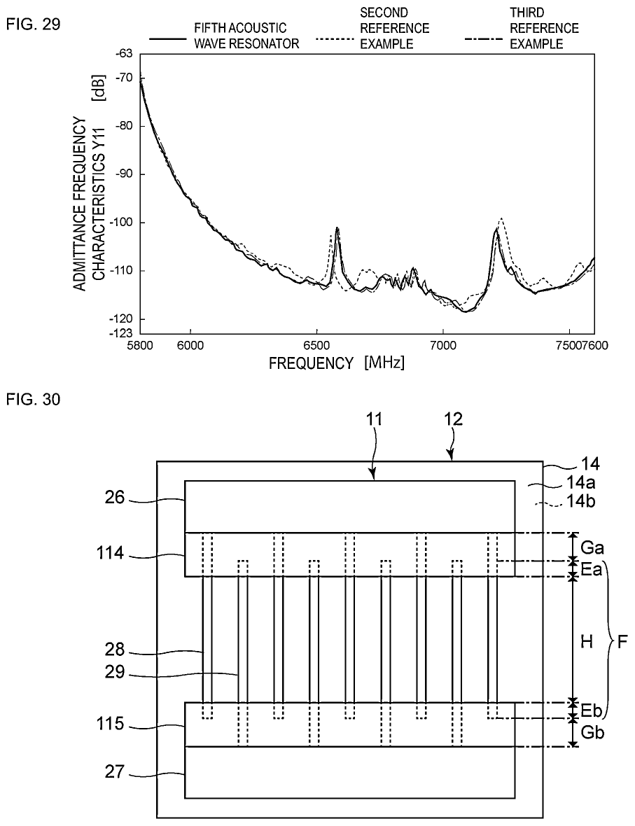

FIG. 29 is a view showing the admittance frequency characteristics of the fifth acoustic wave resonator in the eleventh example embodiment, and the acoustic wave resonators in the second reference example and the third reference example.

As shown in FIG. 29, in the fifth acoustic wave resonator, the loss does not particularly deteriorate except for the frequency on the high band side in the vicinity of about 7600 MHZ, for example. The reason is that rotated Y-cut lithium niobate is used for the piezoelectric layer of the fifth acoustic wave resonator. Furthermore, in the fifth acoustic wave resonator, the mass addition film does not overlap the tip of the electrode finger in plan view.

Similarly, in the second reference example and the third reference example, deterioration in the loss is small except for the frequency on the high band side in the vicinity of about 7600 MHz, for example. For these reasons, it can be understood that a difference in characteristics is small when the positional deviation of the mass addition film is approximately 150 nm, for example.

In the series arm resonator, even when the loss is large at the frequency on the high band side, the influence on the filter characteristics is small. As described above, in the fifth acoustic wave resonator, the loss does not particularly deteriorate except for the frequency on the high band side in the vicinity of about 7600 MHZ, for example. Therefore, since the fifth acoustic wave resonator is used as the series arm resonator, the filter characteristics are less likely to deteriorate.

Furthermore, in the third acoustic wave resonator and the fifth acoustic wave resonator, the thickness of the mass addition film which can effectively improve the loss, and the dimension in the electrode finger extending direction of the gap region are examined.

In the third acoustic wave resonator, when the dimension in the electrode finger extending direction of the gap region is approximately 1.5 μm, for example, the loss can be effectively improved.

When the thickness of the mass addition film is about 25 nm or larger and about 35 nm or smaller, for example, the loss can be effectively improved.

On the other hand, in the fifth acoustic wave resonator, when the dimension in the electrode finger extending direction of the gap region is approximately 3 μm, for example, the loss can be effectively improved. When the thickness of the mass addition film is about 15 nm or larger and about 25 nm or smaller, for example, the loss can be effectively improved.

For these reasons, it is preferable that the thickness of the mass addition film of the third acoustic wave resonator which is the parallel arm resonator is larger than the thickness of the mass addition film of the fifth acoustic wave resonator which is the series arm resonator. It is preferable that the dimension in the electrode finger extending direction of the gap region in the third acoustic wave resonator which is the parallel arm resonator is equal to or smaller than the dimension in the electrode finger extending direction of the gap region in the fifth acoustic wave resonator which is the series arm resonator. In this manner, the loss can be improved in the third acoustic wave resonator and the fifth acoustic wave resonator. In this manner, the filter characteristics of the filter device can be improved.

In the filter device according to the present invention, it is preferable that at least one third acoustic wave resonator is the parallel arm resonator. The third acoustic wave resonator may be the series arm resonator. On the other hand, it is preferable that at least one fifth acoustic wave resonator is the series arm resonator. The fifth acoustic wave resonator may be the parallel arm resonators.

Hereinafter, a configuration of a filter device according to a twelfth example embodiment will be described. In the twelfth example embodiment, in addition to the third to fifth acoustic wave resonators, a sixth acoustic wave resonator is provided.

More specifically, with reference to FIG. 25, the series arm resonator S11 and the parallel arm resonator P11 are the third acoustic wave resonators. The series arm resonator S12 is the fourth acoustic wave resonator. The series arm resonator S13 and the parallel arm resonator P12 are the fifth acoustic wave resonators. The series arm resonator S14 and the parallel arm resonator P13 are the sixth acoustic wave resonators. In this way, the sixth acoustic wave resonator may be used as the series arm resonator, or may be used as the parallel arm resonator. The disposition of the third to sixth acoustic wave resonators shown here is an example, and the disposition of the third to sixth acoustic wave resonators is not limited to the above-described example.

In the filter device of the twelfth example embodiment as well, as in the tenth example embodiment and the eleventh example embodiment, the third acoustic wave resonator which is an acoustic wave device according to an example embodiment of the present invention is used. Therefore, the unnecessary waves can be reduced or prevented in the vicinity of the resonant frequency or in the vicinity of the anti-resonant frequency of the acoustic wave resonator in the filter device. Therefore, it is possible to reduce or prevent deterioration in the filter characteristics.

Hereinafter, the sixth acoustic wave resonator will be described.

FIG. 30 is a schematic plan view of the sixth acoustic wave resonator in the twelfth example embodiment.

In the sixth acoustic wave resonator, the piezoelectric layer 14 of the piezoelectric substrate 12 includes rotated Y-cut lithium niobate. The sixth acoustic wave resonator includes the IDT electrode 11, and the pair of the mass addition film 114 and the mass addition film 115. The mass addition film 114 and the mass addition film 115 have a strip shape.

The mass addition film 114 is provided over the first edge region Ea and the first gap region Ga. The mass addition film 114 is continuously provided to overlap the plurality of electrode fingers and the region between the electrode fingers in plan view.

In the twelfth example embodiment, the mass addition film 114 is provided in the whole first gap region Ga in the electrode finger extending direction. Therefore, the dimension in the electrode finger extending direction of the portion provided in the first gap region Ga in the mass addition film 114 is the same as the dimension in the electrode finger extending direction of the first gap region Ga.

Similarly, the mass addition film 115 is provided over the second edge region Eb and the second gap region Gb. The mass addition film 115 is continuously provided to overlap the plurality of electrode fingers and the region between the electrode fingers in plan view. The dimension in the electrode finger extending direction of the portion provided in the second gap region Gb in the mass addition film 115 is the same as the dimension in the electrode finger extending direction of the second gap region Gb.

In the sixth acoustic wave resonator, the portion provided in each gap region of each mass addition film may be located in a portion of the gap region in the electrode finger extending direction. Alternatively, in the sixth acoustic wave resonator, at least one of the mass addition film 114 and the mass addition film 115 may overlap the busbar in plan view. In the sixth acoustic wave resonator, the mass addition film may be provided over at least one edge region of the pair of edge regions and the gap region adjacent to the edge region.

A single sixth acoustic wave resonator is prepared, and the admittance frequency characteristics are measured. The admittance frequency characteristics of the third acoustic wave resonator and the fifth acoustic wave resonator are also shown together.

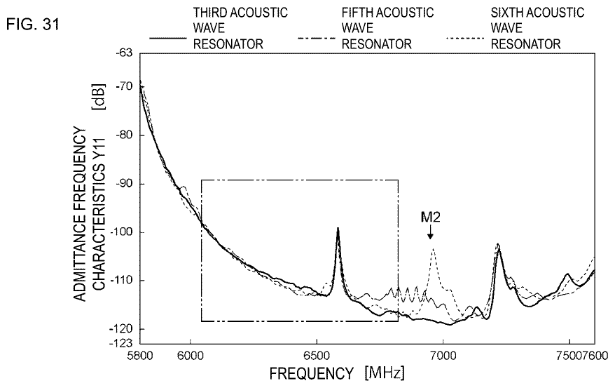

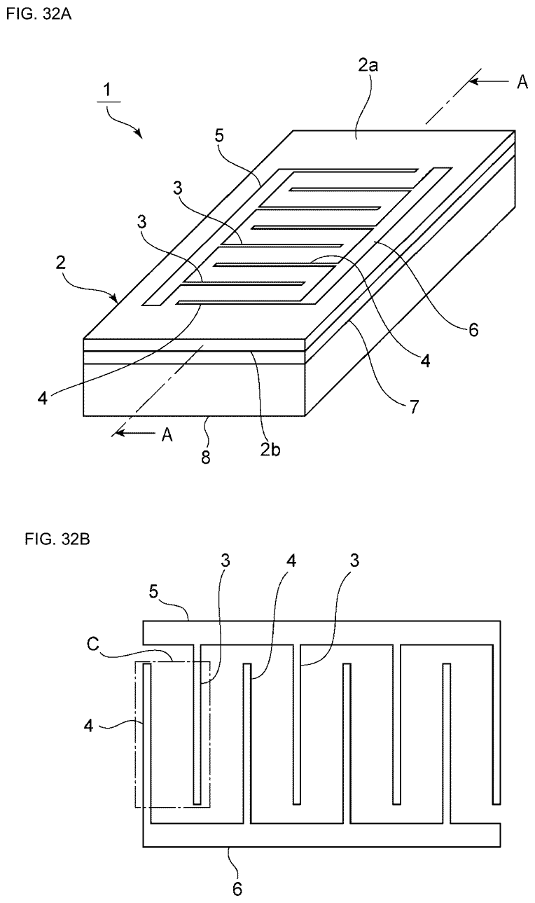

FIG. 31 is a view showing the admittance frequency characteristics of the third acoustic wave resonator, the fifth acoustic wave resonator, and the sixth acoustic wave resonator in the twelfth example embodiment.

As shown in FIG. 31, in the third acoustic wave resonator and the fifth acoustic wave resonator, the unnecessary waves are reduced or prevented in the vicinity of the anti-resonant frequency. On the other hand, in the sixth acoustic wave resonator, the unnecessary waves are generated in the vicinity of the anti-resonant frequency. These are the unnecessary waves caused by the mass addition film 114 and the mass addition film 115.

In the filter device of the twelfth example embodiment, the third to fifth acoustic wave resonators are provided in addition to the sixth acoustic wave resonator. In this manner, the influence on the filter characteristics of the unnecessary waves can be reduced. In addition, as shown in FIG. 31, the loss is small in the sixth acoustic wave resonator. Therefore, in the present example embodiment, deterioration in the filter characteristics in the filter device can be reduced or prevented.

Furthermore, in the sixth acoustic wave resonator, the thickness of the mass addition film which can effectively improve the loss, and the dimension in the electrode finger extending direction of the gap region are examined.

In the sixth acoustic wave resonator, when the dimension in the electrode finger extending direction of the gap region is approximately 3 μm, for example, the loss can be effectively improved. When the thickness of the mass addition film is about 10 nm or larger and about 20 nm or smaller, for example, the loss can be effectively improved.

On the other hand, as described above, in the fifth acoustic wave resonator, when the dimension in the electrode finger extending direction of the gap region is approximately 3 μm, for example, the loss can be effectively improved. When the thickness of the mass addition film is about 15 nm or larger and about 25 nm or smaller, for example, the loss can be effectively improved.

For these reasons, when the sixth acoustic wave resonator is used as the parallel arm resonator and the fifth acoustic wave resonator is used as the series arm resonator, it is preferable that the thickness of the mass addition film of the sixth acoustic wave resonator is smaller than the thickness of the mass addition film of the fifth acoustic wave resonator. In this manner, the loss can be improved in the fifth acoustic wave resonator and the sixth acoustic wave resonator. Therefore, deterioration in the filter characteristics in the filter device can be more reliably reduced or prevented.

In both the fifth acoustic wave resonator and the sixth acoustic wave resonator, when the dimension in the electrode finger extending direction of the gap region is approximately 3 μm, for example, the loss can be effectively improved. When the dimension in the electrode finger extending direction of the gap region is large, it is easy to increase the area of the mass addition film. When the area of the mass addition film is large, the unnecessary waves generated at the frequency on the high band side are reduced or prevented.

For this reason, it is preferable that the dimension in the electrode finger extending direction of the gap region in the sixth acoustic wave resonator which is the parallel arm resonator is equal to or larger than the dimension in the electrode finger extending direction of the gap region of the fifth acoustic wave resonator which is the series arm resonator. In this manner, in the sixth acoustic wave resonator, the unnecessary waves caused by the mass addition film can be reduced or prevented. Therefore, deterioration in the filter characteristics in the filter device can be more reliably reduced or prevented.

Hereinafter, details of the thickness shear mode will be described. The “electrode” in the IDT electrode (to be described later) corresponds to an electrode finger according to an example embodiment of the present invention. The support in the following example corresponds to a support substrate according to an example embodiment of the present invention.

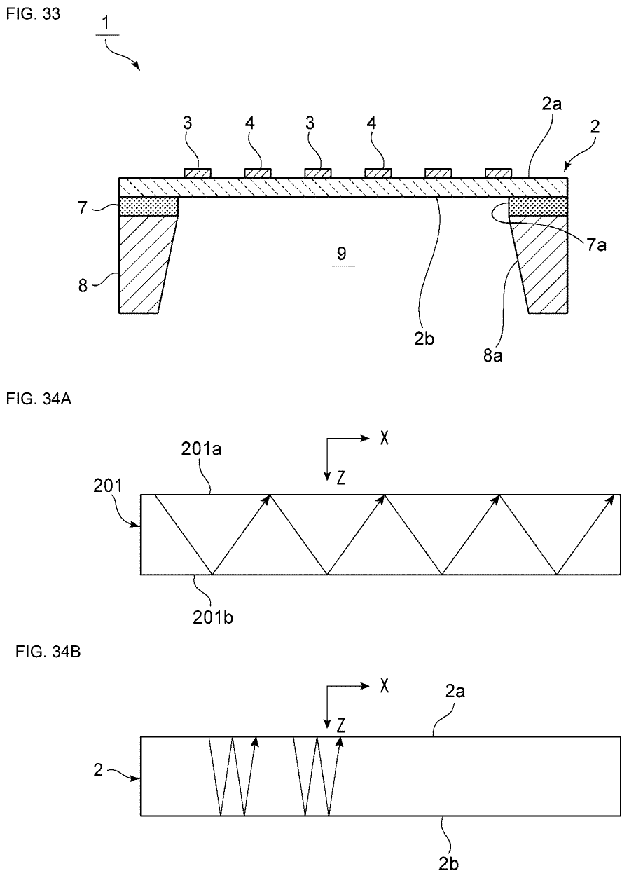

FIG. 32A is a schematic perspective view showing an appearance of the acoustic wave device using the bulk wave in the thickness shear mode, FIG. 32B is a plan view showing an electrode structure on the piezoelectric layer, and FIG. 33 is a cross-sectional view of a portion taken along line A-A in FIG. 32A.

An acoustic wave device 1 includes a piezoelectric layer 2 including LiNbO₃. The piezoelectric layer 2 may include LiTaO₃. The cut-angle of LiNbO₃ or LiTaO₃ is Z-cut angle, but may instead be a rotated Y-cut or X-cut angle. The thickness of the piezoelectric layer 2 is not particularly limited, but is preferably about 40 nm or larger and about 1000 nm or smaller, and more preferably about 50 nm or larger and about 1000 nm or smaller, for example, in order to effectively excite the thickness shear mode. The piezoelectric layer 2 has first and second main surfaces 2a and 2b facing each other. Electrodes 3 and 4 are provided on the first main surface 2a. Here, the electrode 3 is an example of a “first electrode”, and the electrode 4 is an example of a “second electrode”. In FIGS. 32A and 32B, the plurality of electrodes 3 are a plurality of first electrode fingers connected to a first busbar 5. The plurality of electrodes 4 are a plurality of second electrode fingers connected to a second busbar 6. The plurality of electrodes 3 and the plurality of electrodes 4 are interdigitated with each other. The electrode 3 and the electrode 4 have a rectangular shape, and have a length direction. The electrode 3 and the electrode 4 adjacent thereto face each other in a direction perpendicular to the length direction. Both the length direction of the electrodes 3 and 4 and the direction perpendicular to the length direction of the electrodes 3 and 4 are directions intersecting the thickness direction of the piezoelectric layer 2. Therefore, the electrode 3 and the electrode 4 adjacent thereto face each other in the direction intersecting the thickness direction of the piezoelectric layer 2. In addition, the length direction of the electrodes 3 and 4 may be replaced with the direction perpendicular to the length direction of the electrodes 3 and 4 shown in FIGS. 32A and 32B. That is, in FIGS. 32A and 32B, the electrodes 3 and 4 may extend in the extending direction of the first busbar 5 and the second busbar 6. In this case, the first busbar 5 and the second busbar 6 extend in the extending direction of the electrodes 3 and 4 in FIGS. 32A and 32B. A plurality of pairs of structures in which the electrode 3 connected to one potential and the electrode 4 connected to the other potential are adjacent to each other are provided in the direction perpendicular to the length direction of the electrodes 3 and 4. Here, a case where the electrodes 3 and 4 are adjacent to each other does not mean a case where the electrodes 3 and 4 are disposed to be in direct contact with each other, but mean a case where the electrodes 3 and 4 are disposed with an interval therebetween. In addition, when the electrodes 3 and 4 are adjacent to each other, the electrode connected to a hot electrode or a ground electrode, including the other electrodes 3 and 4, is not disposed between the electrodes 3 and 4. The number of pairs does not need to be integer pairs, but may be 1.5 pairs, 2.5 pairs, or the like. The center-to-center distance, that is, a pitch between the electrodes 3 and 4 is preferably in a range of about 1 μm or larger and about 10 μm or smaller, for example. In addition, the widths of the electrodes 3 and 4, that is, the dimensions of the electrodes 3 and 4 in the facing direction are preferably in a range of about 50 nm or larger and about 1000 nm or smaller, and more preferably in a range of about 150 nm or larger and about 1000 nm or smaller, for example. The center-to-center distance between the electrodes 3 and 4 is a distance connecting the center of the dimension (width dimension) of the electrode 3 in the direction perpendicular to the length direction of the electrode 3 and the center of the dimension (width dimension) of the electrode 4 in the direction perpendicular to the length direction of the electrode 4.

In the acoustic wave device 1, since the Z-cut piezoelectric layer is used, the direction perpendicular to the length direction of the electrodes 3 and 4 is a direction perpendicular to a polarization direction of the piezoelectric layer 2. When piezoelectric materials with different cut-angles are used as the piezoelectric layer 2, this case is an exception. Here, description of “perpendicular” is not limited to being strictly perpendicular, but may be substantially perpendicular (angle defined between the direction perpendicular to the length direction of the electrodes 3 and 4 and the polarization direction falls within a range of about 90°+10°, for example).

A support 8 is laminated on the second main surface 2b side of the piezoelectric layer 2 with an insulating layer 7 interposed therebetween. The insulating layer 7 and the support 8 have a frame shape, and include through holes 7a and 8a as shown in FIG. 33. In this manner, a cavity 9 is formed. The cavity 9 is provided not to disturb the vibration of an excitation region C of the piezoelectric layer 2. Therefore, the support 8 is laminated on the second main surface 2b with the insulating layer 7 interposed therebetween at a position not overlapping the portion where at least one pair of electrodes 3 and 4 are provided. The insulating layer 7 does not have to be provided. Therefore, the support 8 can be directly or indirectly laminated on the second main surface 2b of the piezoelectric layer 2.

The insulating layer 7 includes silicon oxide. In addition to silicon oxide, an appropriate insulating material such as silicon oxynitride or alumina can be used. The support 8 includes Si. A plane orientation of a surface of Si on the piezoelectric layer 2 side may be (100), (110), or (111). It is desirable that Si included in the support 8 has a high resistivity of about 4 kΩcm or higher, for example. The support 8 can also be including an appropriate insulating material or semiconductor material.

Examples of the material of the support 8 include piezoelectric materials such as aluminum oxide, lithium tantalate, lithium niobate, and quartz crystal, various ceramics such as alumina, magnesia, sapphire, silicon nitride, aluminum nitride, silicon carbide, zirconia, cordierite, mullite, steatite, or forsterite, dielectrics such as diamond or glass, or semiconductors such as gallium nitride.

The plurality of electrodes 3 and 4 and the first and second busbars 5 and 6 may include appropriate metal or alloys such as Al and AlCu alloys. In the acoustic wave device 1, the electrodes 3 and 4 and the first and second busbars 5 and 6 have a structure in which Al films are laminated on a Ti film. An adhesion layer other than the Ti film may be used.

During driving, an AC voltage is applied between the plurality of electrodes 3 and the plurality of electrodes 4. More specifically, the AC voltage is applied between the first busbar 5 and the second busbar 6. In this manner, it is possible to obtain the resonance characteristics using the bulk wave in the thickness shear mode excited in the piezoelectric layer 2. In the acoustic wave device 1, when the thickness of the piezoelectric layer 2 is defined as d and the center-to-center distance between any adjacent electrodes 3 and 4 in the plurality of pairs of electrodes 3 and 4 is defined as p, d/p is about 0.5 or smaller, for example. In this manner, the bulk wave in the thickness shear mode is effectively excited, and satisfactory resonance characteristics can be obtained. More preferably, d/p is about 0.24 or smaller, and in this case, more satisfactory resonance characteristics can be obtained.

In the acoustic wave device 1, since the above-described configuration is provided, even when the number of pairs of the electrodes 3 and 4 is reduced for size reduction, a Q factor is less likely to be decreased. The reason is that a propagation loss is small even when the number of electrode fingers in reflectors on both sides is reduced. In addition, the number of electrode fingers can be reduced by using the bulk wave in the thickness shear mode. A difference between a Lamb wave used for the acoustic wave device and the bulk wave in the thickness shear mode will be described with reference to FIGS. 34A and 34B.

FIG. 34A is a schematic elevational cross-sectional view showing the Lamb wave that propagates through the piezoelectric film of the acoustic wave device as disclosed in Japanese Unexamined Patent Application Publication No. 2012-257019. Here, the wave propagates through a piezoelectric film 201 as indicated by an arrow. Here, in the piezoelectric film 201, a first main surface 201a and a second main surface 201b face each other, and the thickness direction connecting the first main surface 201a and the second main surface 201b is a Z-direction. An X-direction is a direction in which the electrode fingers of the IDT electrodes are aligned. As shown in FIG. 34A, in the Lamb wave, the wave propagates in the X-direction as shown in the drawing. Since the wave is a plate wave, the piezoelectric film 201 vibrates as a whole. Since the wave propagates in the X-direction, the reflectors are disposed on both sides to obtain the resonance characteristics. Therefore, the propagation loss of the wave occurs, and the Q factor is decreased when the size is reduced, that is, when the number of pairs of the electrode fingers is reduced.

In contrast, as shown in FIG. 34B, in the acoustic wave device 1, since vibration displacement occurs in a thickness shear direction, the waves mostly propagate and resonate in the direction connecting the first main surface 2a and the second main surface 2b of the piezoelectric layer 2, that is, the Z-direction. That is, an X-direction component of the wave is significantly smaller than a Z-direction component of the wave. In addition, since the resonance characteristics are obtained by the propagation of the wave in the Z-direction, the propagation loss is less likely to occur even when the number of the electrode fingers of the reflector is reduced. Therefore, even when the number of pairs of the electrodes including the electrodes 3 and 4 is reduced for size reduction, the Q factor is less likely to be decreased.

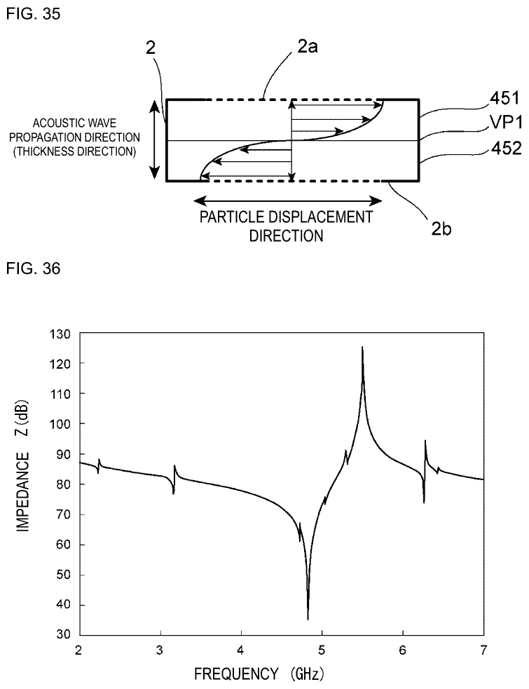

As shown in FIG. 35, amplitude directions of the bulk waves in the thickness shear mode are opposite to each other between a first region 451 included in the excitation region C of the piezoelectric layer 2 and a second region 452 included in the excitation region C. FIG. 35 schematically shows the bulk waves when a voltage is applied between the electrodes 3 and 4 such that the electrode 4 is has a higher potential than the electrode 3. The first region 451 is a region of the excitation region C between a virtual plane VP1 perpendicular to the thickness direction of the piezoelectric layer 2 and bisecting the piezoelectric layer 2, and the first main surface 2a. The second region 452 is a region of the excitation region C between the virtual plane VP1 and the second main surface 2b.

As described above, in the acoustic wave device 1, although at least one pair of electrodes including the electrodes 3 and 4 are disposed, the waves do not propagate in the X-direction. Therefore, there does not need to be a plurality of pairs of the electrodes including the electrodes 3 and 4. That is, at least one pair of electrodes may be provided.

For example, the electrode 3 is the electrode connected to the hot potential, and the electrode 4 is the electrode connected to the ground potential. The electrode 3 may be connected to the ground potential, and the electrode 4 may be connected to the hot potential. In the acoustic wave device 1, as described above, at least one pair of electrodes is the electrodes connected to the hot potential or the electrodes connected to the ground potential, and a floating electrode is not provided.

FIG. 36 is a view showing the resonance characteristics of the acoustic wave device shown in FIG. 33. Example design parameters of the acoustic wave device 1 having the resonance characteristics are as follows.

Piezoelectric layer 2: LiNbO₃ with Euler angles (0°, 0°, 90°), thickness=about 400 nm.

When viewed in the direction perpendicular to the length direction of the electrodes 3 and 4, the length of the region in which the electrodes 3 and 4 overlap each other, that is, the length of the excitation region C=about 40 μm, the number of pairs of the electrodes including the electrodes 3 and 4=21 pairs, the center-to-center distance between the electrodes=about 3 μm, the width of the electrodes 3 and 4=about 500 nm, and d/p=about 0.133.

Insulating layer 7: silicon oxide film having the thickness of about 1 μm.

Support 8: Si.

The length of the excitation region C is the dimension in the length direction of the electrodes 3 and 4 of the excitation region C.

In the acoustic wave device 1, an electrode-to-electrode distance of the electrode pair including the electrodes 3 and 4 is set to be equal in all of the plurality of pairs. That is, the electrodes 3 and 4 are disposed at an equal pitch.

As is clear from FIG. 36, satisfactory resonance characteristics with the fractional bandwidth of about 12.5%, for example, are obtained despite there being no reflectors.

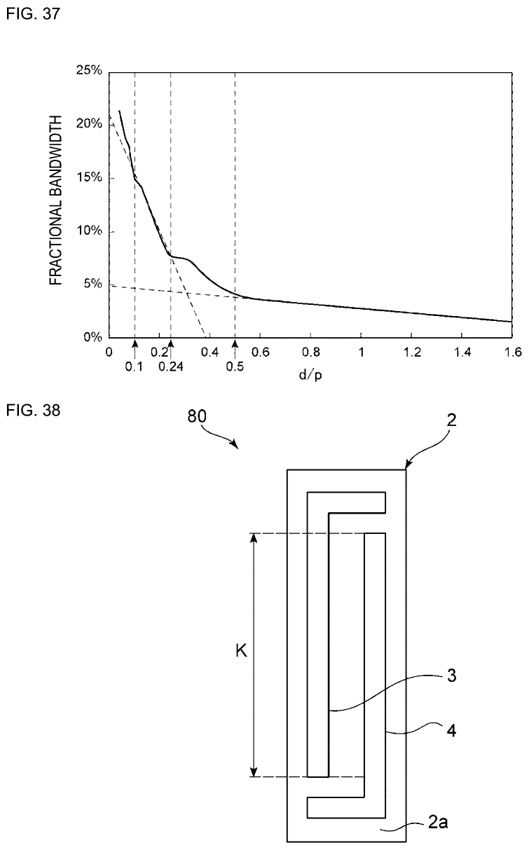

Incidentally, when the thickness of the piezoelectric layer 2 is defined as d and the center-to-center distance of the electrodes 3 and 4 is defined as p, in the acoustic wave device 1, as described above, d/p is about 0.5 or smaller, and is more preferably about 0.24 or smaller, for example. This configuration will be described with reference to FIG. 37.

The plurality of acoustic wave devices are obtained by changing d/p as in the acoustic wave device that obtains the resonance characteristics shown in FIG. 36. FIG. 37 is a view showing a relationship between d/p and a fractional bandwidth as the resonator of the acoustic wave device.

As is clear from FIG. 37, when d/p>about 0.5, the fractional bandwidth is smaller than about 5% even when d/p is adjusted, for example. In contrast, in a case of d/p≤ about 0.5, when d/p is changed within this range, the fractional bandwidth can be about 5% or larger, for example, that is, a resonator having a high coupling coefficient can be formed. In addition, when d/p is about 0.24 or smaller, the fractional bandwidth can be increased to about 7% or larger, for example. In addition, when d/p is adjusted within this range, a resonator having a wider fractional bandwidth can be obtained, and a resonator having a higher coupling coefficient can be realized. Therefore, it can be understood that the resonator using the bulk wave in the thickness shear mode and having the high coupling coefficient can be formed by adjusting d/p to about 0.5 or smaller, for example.

FIG. 38 is a plan view of the acoustic wave device using the bulk wave in the thickness shear mode. In an acoustic wave device 80, the pair of electrodes including the electrode 3 and electrode 4 is provided on the first main surface 2a of the piezoelectric layer 2. K in FIG. 38 is an intersecting width. As described above, in an acoustic wave device according to an example embodiment of the present invention, the number of pairs of the electrodes may be one pair. Even in this case, when d/p is about 0.5 or smaller, the bulk wave in the thickness shear mode can be effectively excited.

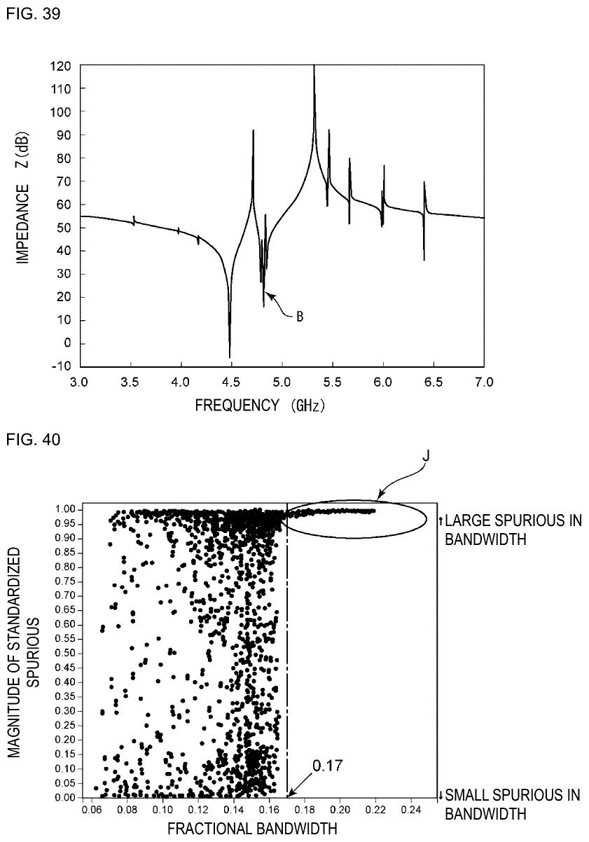

In the acoustic wave device 1, preferably, it is desirable that a metallization ratio MR of any adjacent electrodes 3 and 4 in the plurality of electrodes 3 and 4 to the excitation region C which is the region in which the adjacent electrodes 3 and 4 overlap each other when viewed in the facing direction satisfies MR≤ about 1.75 (d/p)+0.075. In this case, the spurious can be effectively reduced. This configuration will be described with reference to FIGS. 39 and 40. FIG. 39 is a reference view showing an example of the resonance characteristics of the acoustic wave device 1. The spurious indicated by an arrow B appears between the resonant frequency and the anti-resonant frequency. In the example, d/p=about 0.08 is set, and the Euler angles (0°, 0°, 90°) of LiNbO₃ are set. In addition, the metallization ratio MR=about 0.35 is set, for example.

The metallization ratio MR will be described with reference to FIG. 32B. In the electrode structure of FIG. 32B, in a case of focusing on the pair of electrodes 3 and 4, only the pair of electrodes 3 and 4 are provided. In this case, a portion surrounded by one-dot chain line is the excitation region C. The excitation region C includes a region of the electrode 3 that overlaps the electrode 4, a region of the electrode 4 that overlaps the electrode 3, and a region in which the electrode 3 and the electrode 4 overlap each other in the region between the electrode 3 and the electrode 4, when the electrode 3 and the electrode 4 are viewed in the direction perpendicular to the length direction of the electrodes 3 and 4, that is, in the facing direction. The ratio of an area of the electrodes 3 and 4 inside the excitation region C with respect to an area of the excitation region C is the metallization ratio MR. That is, the metallization ratio MR is a ratio of an area of the metallization portion with respect to an area of the excitation region C.

When the plurality of pairs of electrodes are provided, a ratio of the metallization portion included in the entire excitation region with respect to a total area of the excitation region may be MR.

FIG. 40 is a view showing a relationship between the fractional bandwidth and a phase rotation amount of the impedance of the spurious standardized at 180 degrees as the magnitude of the spurious when a large number of acoustic wave resonators are configured according to a form of the acoustic wave device 1. The fractional bandwidth is adjusted by changing the film thickness of the piezoelectric layer and the dimensions of the electrodes. In addition, FIG. 40 shows results when the piezoelectric layer including Z-cut LiNbO₃ is used, but shows the same tendency when the piezoelectric layer having other cut-angles is used.

In a region surrounded by an ellipse J in FIG. 40, the spurious is as large as about 1.0, for example. As is clear from FIG. 40, when the fractional bandwidth exceeds about 0.17, that is, exceeds about 17%, for example, a large spurious with a spurious level of 1 or larger appears inside a pass band even when the parameters forming the fractional bandwidth are changed. That is, as in the resonance characteristics shown in FIG. 39, a large spurious indicated by an arrow B appears inside the band. Therefore, the fractional bandwidth is preferably about 17% or smaller, for example. In this case, the spurious can be reduced by adjusting the film thickness of the piezoelectric layer 2 and the dimensions of the electrodes 3 and 4.

FIG. 41 is a view showing a relationship between d/2p, the metallization ratio MR, and the fractional bandwidth. In the acoustic wave device described above, various acoustic wave devices having different d/2p and MR are configured, and the fractional bandwidth is measured. A hatched portion on a right side of a broken line D in FIG. 41 is a region in which the fractional bandwidth is about 17% or smaller, for example. A boundary between the hatched region and a non-hatched region is expressed by MR=about 3.5 (d/2p)+0.075, for example. That is, MR=about 1.75 (d/p)+0.075, for example. Therefore, preferably, MR≤ about 1.75 (d/p)+0.075, for example. In this case, it is easy to set the fractional bandwidth to about 17% or smaller, for example. It is more preferable to set a region on a right side of MR=about 3.5 (d/2p)+0.05, for example, indicated by a one-dot chain line D1 in FIG. 41. That is, in a case of MR≤ about 1.75 (d/p)+0.05, the fractional bandwidth can be reliably set to about 17% or smaller, for example.

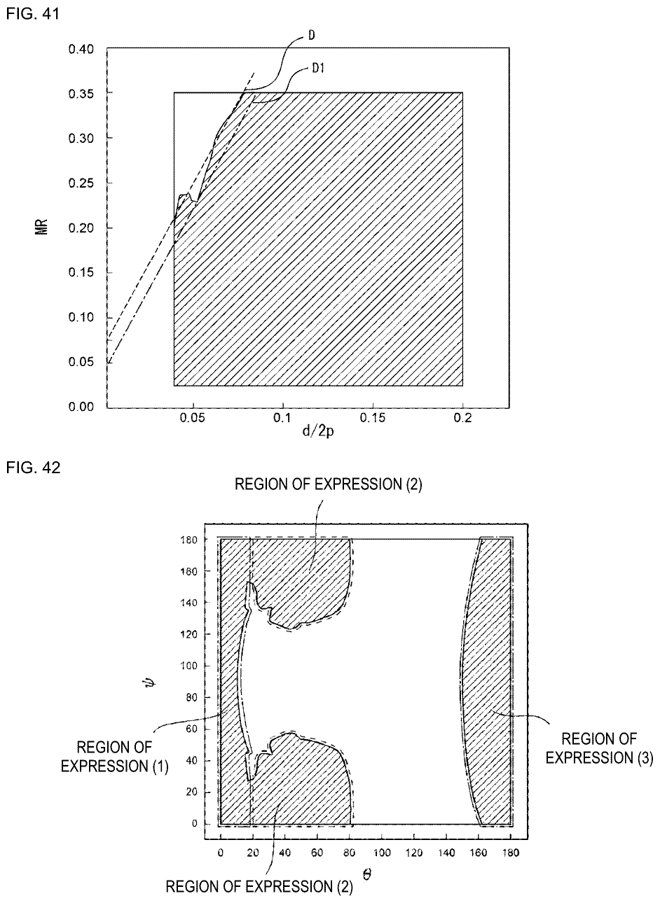

FIG. 42 is a view showing a map of the fractional bandwidth with respect to Euler angles (0°, θ, ψ) of LiNbO₃ when d/p is infinitely close to 0. A hatched portion in FIG. 42 is a region in which the fractional bandwidth of, for example, at least about 5% or larger is obtained, and when a range of the region is approximated, the range is represented by Expression (1), Expression (2), and Expression (3).

(0°+10°,0° to 20°, any ψ) Expression (1)

(0°+10°,20° to 80°,0° to 60°(1−(θ−50)²/900)^{1/2}) or (0°+10°,20° to 80°,[180°−60°(1−(θ−50)²/900)^{1/2}] to 180°) Expression (2)

(0°±10°,[180°−30°(1−(ψ−90)²/8100)^{1/2}] to 180°, any ¢) Expression (3)

Therefore, in a case of the Euler angle range of Expression (1), Expression (2), or Expression (3), it is preferable since the fractional bandwidth can be sufficiently widened. The same applies to a case where the piezoelectric layer 2 is the lithium tantalate layer.

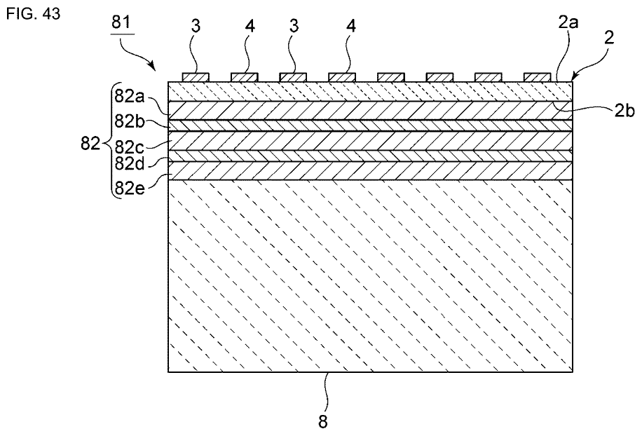

FIG. 43 is an elevational cross-sectional view of the acoustic wave device having the acoustic multilayer film.

In an acoustic wave device 81, an acoustic multilayer film 82 is laminated on the second main surface 2b of the piezoelectric layer 2. The acoustic multilayer film 82 has a multilayer structure of low acoustic impedance layers 82a, 82c, and 82e having a relatively low acoustic impedance and high acoustic impedance layers 82b and 82d having a relatively high acoustic impedance. When the acoustic multilayer film 82 is used, the bulk wave in the thickness shear mode can be confined in the piezoelectric layer 2 without using the cavity 9 in the acoustic wave device 1. In the acoustic wave device 81 as well, the resonance characteristics based on the bulk wave in the thickness shear mode can be obtained by setting d/p to about 0.5 or smaller, for example. In the acoustic multilayer film 82, the number of laminated layers of the low acoustic impedance layers 82a, 82c, and 82e and the high acoustic impedance layers 82b and 82d is not particularly limited. At least one layer of the high acoustic impedance layers 82b and 82d may be disposed on a side farther from the piezoelectric layer 2 than the low acoustic impedance layers 82a, 82c, and 82e.

The low acoustic impedance layers 82a, 82c, and 82e and the high acoustic impedance layers 82b and 82d can be including an appropriate material as long as the above-described relationship of the acoustic impedance is satisfied. Examples of the materials of the low acoustic impedance layers 82a, 82c, and 82e include silicon oxide, silicon oxynitride, and the like. In addition, examples of the materials of the high acoustic impedance layers 82b and 82d include alumina, silicon nitride, metal, and the like.

In the acoustic wave devices according to the first to eighth example embodiments and each of the modification examples, for example, the acoustic multilayer film 82 shown in FIG. 43 may be provided as an acoustic reflection film between the support and the piezoelectric layer. Specifically, the support and the piezoelectric layer may be disposed such that at least a portion of the support and at least a portion of the piezoelectric layer face each other across the acoustic multilayer film 82. In this case, in the acoustic multilayer film 82, the low acoustic impedance layer and the high acoustic impedance layer may be alternately laminated. The acoustic multilayer film 82 may be the acoustic reflector in the acoustic wave device.

In the acoustic wave devices according to the first to eighth example embodiments and each of the modification examples which use the bulk wave in the thickness shear mode, as described above, d/p is preferably about 0.5 or smaller, and is more preferably about 0.24 or smaller, for example. In this manner, more satisfactory resonance characteristics can be obtained. Furthermore, in the excitation regions in the acoustic wave devices according to the first to eighth example embodiments and each of the modification examples which use the bulk wave in the thickness shear mode, as described above, MR≤ about 1.75 (d/p)+0.075 is preferably satisfied. In this case, the spurious can be more reliably reduced or prevented.

It is preferable that the piezoelectric layers in the acoustic wave devices according to the first to eighth example embodiments and each of the modification examples which use the bulk wave in the thickness shear mode is the lithium niobate layer or the lithium tantalate layer. In addition, it is preferable that the Euler angles (φ, θ, ψ) of lithium niobate or lithium tantalate of the piezoelectric layer fall within the range of Expression (1), Expression (2), or Expression (3). In this case, the fractional bandwidth can be sufficiently widened.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A acoustic wave device comprising:
a support including a support substrate;
a piezoelectric layer provided on the support and including lithium tantalate or lithium niobate; and
an IDT electrode provided on the piezoelectric layer and including a pair of busbars and a plurality of electrode fingers; wherein
in plan view in a lamination direction of the support and the piezoelectric layer, an acoustic reflector overlaps with at least a portion of the IDT electrode in the support;
when a thickness of the piezoelectric layer is defined as d and a center-to-center distance between the electrode fingers adjacent to each other is defined as p, d/p is about 0.5 or smaller;
some electrode fingers of the plurality of electrode fingers are connected to one busbar of the pair of busbars, remaining electrode fingers of the plurality of electrode fingers are connected to an other busbar, and the some electrode fingers connected to the one busbar and the remaining electrode fingers connected to the other busbar are interdigitated with each other;
an extending direction of the plurality of electrode fingers is defined as an electrode finger extending direction, and a direction perpendicular to the electrode finger extending direction is defined as an electrode finger facing direction, when viewed in the electrode finger facing direction, a region in which the adjacent electrode fingers overlap each other is an intersecting region, a region located between the intersecting region and the pair of busbars is a pair of gap regions, and the intersecting region includes a central region and a pair of edge regions positioned with the central region interposed therebetween in the electrode finger extending direction;
the acoustic wave device further includes a plurality of mass addition films provided over at least one edge region of the pair of edge regions and the gap region adjacent to the at least one edge region, and aligned in the electrode finger facing direction; and
the plurality of mass addition films are not located in at least a portion between the adjacent electrode fingers.

2. The acoustic wave device according to claim 1, wherein the plurality of mass addition films include a plurality of first mass addition films provided over one of the edge regions and one of the gap regions, and a plurality of second mass addition films provided over an other of the edge regions and an other of the gap regions.

3. The acoustic wave device according to claim 1, wherein
the plurality of mass addition films include the mass addition film including a portion laminated with the electrode finger; and
in a portion where the mass addition film and the electrode finger are laminated, the piezoelectric layer, the electrode finger, and the mass addition film are laminated in an order of the piezoelectric layer, the electrode finger, and the mass addition film.

4. The acoustic wave device according to claim 1, wherein
the plurality of mass addition films include the mass addition film including a portion laminated with the electrode finger; and
in a portion where the mass addition film and the electrode finger are laminated, the piezoelectric layer, the mass addition film, and the electrode finger are laminated in an order of the piezoelectric layer, the mass addition film, and the electrode finger.

5. The acoustic wave device according to claim 3, wherein the mass addition film including the portion laminated with the electrode finger includes a portion laminated with a tip portion of the electrode finger.

6. The acoustic wave device according to claim 1, wherein in plan view, the plurality of mass addition films include the mass addition film that surrounds a tip portion of the electrode finger in three directions.

7. The acoustic wave device according to claim 1, wherein the plurality of mass addition films provided in a same edge region and a same gap region include at least one of the mass addition films including a different area in plan view.

8. The acoustic wave device according to claim 1, wherein at least one of the mass addition films extends from the gap region to a portion that overlaps the busbar adjacent to the gap region in plan view.

9. The acoustic wave device according to claim 1, wherein a dimension in the electrode finger extending direction of the gap region is about 1 μm or larger.

10. The acoustic wave device according to claim 9, wherein a dimension in the electrode finger extending direction of the gap region is about 2 μm or larger, and in the gap region, a dimension in the electrode finger extending direction of the mass addition film is about 2 μm or larger.

11. The acoustic wave device according to claim 1, wherein a dielectric film is provided on the piezoelectric layer to cover the IDT electrode.

12. The acoustic wave device according to claim 11, wherein in a portion where the dielectric film and the mass addition film are laminated, the piezoelectric layer, the mass addition film, and the dielectric film are laminated in an order of the piezoelectric layer, the mass addition film, and the dielectric film.

13. The acoustic wave device according to claim 11, wherein in a portion where the dielectric film and the mass addition film are laminated, the piezoelectric layer, the dielectric film, and the mass addition film are laminated in an order of the piezoelectric layer, the dielectric film, and the mass addition film.

14. The acoustic wave device according to claim 11, wherein the dielectric film includes silicon oxide.

15. The acoustic wave device according to claim 1, wherein the mass addition film includes at least one of silicon oxide, tantalum oxide, niobium oxide, tungsten oxide, or hafnium oxide.

16. The acoustic wave device according to claim 1, wherein d/p is about 0.24 or smaller.

17. The acoustic wave device according to claim 1, wherein when viewed in a direction in which the adjacent electrode fingers face each other, a center-to-center region of the adjacent electrode fingers which is an overlapping region of the adjacent electrode fingers is an excitation region, and when a metallization ratio of the plurality of electrode fingers with respect to the excitation region is defined as MR, MR≤ about 1.75 (d/p)+0.075 is satisfied.

18. The acoustic wave device according to claim 1, wherein Euler angles (φ, θ, ψ) of lithium niobate or lithium tantalate of the piezoelectric layer fall within a range of Expression (1), Expression (2), or Expression (3):
(0°+10°,0° to 20°, any ψ) Expression (1);
(0°+10°,20° to 80°,0° to 60° (1−(θ-50)²/900)^{1/2}) or (0°+10°,20° to 80°,[180°-60° (1−(θ-50)²/900)^{1/2}] to 180°) Expression (2);
(0°+10°,[180°-30° (1−(ψ-90)²/8100)^{1/2}] to 180°, any ψ) Expression (3).

19. The acoustic wave device according to claim 1, wherein the acoustic reflector includes a cavity, and the support and the piezoelectric layer are positioned such that a portion of the support and a portion of the piezoelectric layer face each other across the cavity.

20. The acoustic wave device according to claim 1, wherein the acoustic reflector is an acoustic reflection film including a high acoustic impedance layer having a relatively high acoustic impedance and a low acoustic impedance layer having a relatively low acoustic impedance, and the support and the piezoelectric layer are positioned such that at least a portion of the support and at least a portion of the piezoelectric layer face each other across the acoustic reflection film.

21. The acoustic wave device according to claim 1, wherein the piezoelectric layer includes rotated Y-cut lithium niobate.

22. A filter device comprising:
at least one series arm resonator;
at least one parallel arm resonator;
at least one first acoustic wave resonator included in the at least one series arm resonator; and
at least one second acoustic wave resonator included in the at least one parallel arm resonator; wherein
each of the first acoustic wave resonator and the second acoustic wave resonator is the acoustic wave device according to claim 1; and
a thickness of the plurality of mass addition films of the second acoustic wave resonator is smaller than a thickness of the plurality of mass addition films of the first acoustic wave resonator.

23. A filter device comprising:
at least one series arm resonator;
at least one parallel arm resonator;
at least one first acoustic wave resonator included in the at least one series arm resonator; and
at least one second acoustic wave resonator included in the at least one parallel arm resonator; wherein
each of the first acoustic wave resonator and the second acoustic wave resonator is the acoustic wave device according to claim 1; and
an average value of areas of the plurality of mass addition films of the second acoustic wave resonator in plan view is greater than an average value of areas of the plurality of mass addition films of the first acoustic wave resonator in plan view.

24. A filter device comprising:
a plurality of acoustic wave resonators including at least one series arm resonator and at least one parallel arm resonator; wherein
at least one acoustic wave resonator of the series arm resonator and the parallel arm resonator is the acoustic wave device according to claim 21.

25. The filter device according to claim 24, wherein
the series arm resonator and the parallel arm resonator include at least one third acoustic wave resonator and at least one fourth acoustic wave resonator;
the third acoustic wave resonator is the acoustic wave device; and
the fourth acoustic wave resonator includes the support, the piezoelectric layer including rotated Y-cut lithium niobate, and the IDT electrode including the intersecting region and the pair of gap regions, and does not include the mass addition film.

26. The filter device according to claim 25, wherein
at least one of the third acoustic wave resonators is the parallel arm resonator;
all of the fourth acoustic wave resonators are each the series arm resonator; and
a dimension in the electrode finger extending direction of the gap region in the third acoustic wave resonator which is the parallel arm resonator is larger than a dimension in the electrode finger extending direction of the gap region in the fourth acoustic wave resonator.

27. The filter device according to claim 24, wherein
the series arm resonator and the parallel arm resonator include at least one third acoustic wave resonator and at least one fifth acoustic wave resonator;
the third acoustic wave resonator is the acoustic wave device;
the fifth acoustic wave resonator includes the support, the piezoelectric layer including rotated Y-cut lithium niobate, the IDT electrode including the intersecting region and the pair of gap regions, and the mass addition film; and
in the fifth acoustic wave resonator, the mass addition film is provided in at least one gap region of the pair of gap regions, is not provided in the intersecting region, and is continuously provided to overlap the plurality of electrode fingers and a region between the electrode fingers in plan view.

28. The filter device according to claim 27, wherein
at least one of the third acoustic wave resonators is the parallel arm resonator;
at least one of the fifth acoustic wave resonators is the series arm resonator;
a thickness of the mass addition film of the third acoustic wave resonator which is the parallel arm resonator is larger than a thickness of the mass addition film of the fifth acoustic wave resonator which is the series arm resonator; and
a dimension in the electrode finger extending direction of the gap region in the third acoustic wave resonator which is the parallel arm resonator is equal to or smaller than a dimension in the electrode finger extending direction of the gap region in the fifth acoustic wave resonator which is the series arm resonator.

29. The filter device according to claim 24, wherein
the series arm resonator and the parallel arm resonator include at least one third acoustic wave resonator and at least one sixth acoustic wave resonator;
the third acoustic wave resonator is the acoustic wave device;
the sixth acoustic wave resonator includes the support, the piezoelectric layer including rotated Y-cut lithium niobate, the IDT electrode including the intersecting region and the pair of gap regions, and the mass addition film; and
in the sixth acoustic wave resonator, the mass addition film is provided over at least one edge region of the pair of edge regions and the gap region adjacent to the at least one edge region, and is continuously provided to overlap the plurality of electrode fingers and a region between the electrode fingers in plan view.

30. The filter device according to claim 29, wherein
the series arm resonator and the parallel arm resonator include at least one fifth acoustic wave resonator;
the fifth acoustic wave resonator includes the support, the piezoelectric layer including rotated Y-cut lithium niobate, the IDT electrode including the intersecting region and the pair of gap regions, and the mass addition film;
in the fifth acoustic wave resonator, the mass addition film is provided in at least one gap region of the pair of gap regions, is not provided in the intersecting region, and is continuously provided to overlap the plurality of electrode fingers and a region between the electrode fingers in plan view;
at least one of the fifth acoustic wave resonators is the series arm resonator;
at least one of the sixth acoustic wave resonators is the parallel arm resonator;
a thickness of the mass addition film of the sixth acoustic wave resonator which is the parallel arm resonator is smaller than a thickness of the mass addition film of the fifth acoustic wave resonator which is the series arm resonator; and
a dimension in the electrode finger extending direction of the gap region in the sixth acoustic wave resonator which is the parallel arm resonator is equal to or larger than a dimension in the electrode finger extending direction of the gap region in the fifth acoustic wave resonator which is the series arm resonator.

31. The filter device according to claim 29, wherein
the series arm resonator and the parallel arm resonator include at least one fifth acoustic wave resonator;
the fifth acoustic wave resonator includes the support, the piezoelectric layer including rotated Y-cut lithium niobate, the IDT electrode including the intersecting region and the pair of gap regions, and the mass addition film;
in the fifth acoustic wave resonator, the mass addition film is provided in at least one gap region of the pair of gap regions, is not provided in the intersecting region, and is continuously provided to overlap the plurality of electrode fingers and a region between the electrode fingers in plan view; and
at least one of the mass addition films of at least one acoustic wave resonator of the fifth acoustic wave resonator and the sixth acoustic wave resonator extends from the gap region to a portion that overlaps the busbar adjacent to the gap region in plan view.
